(19) United States
(12) Patent Application Publication
(10) Pub. No.: US 2024/0369930 A1
(43) Pub. Date: Nov. 7, 2024

(54) COMPOSITION FOR SPIN-ON CARBON FILM FORMATION, METHOD FOR PRODUCING COMPOSITION FOR SPIN-ON CARBON FILM FORMATION, UNDERLAYER FILM FOR LITHOGRAPHY, RESIST PATTERN FORMATION METHOD, AND CIRCUIT PATTERN FORMATION METHOD

(71) Applicant: Mitsubishi Gas Chemical Company, Inc., Tokyo (JP)

(72) Inventors: Takashi SATO, Hiratsuka-shi, Kanagawa (JP); Masatoshi ECHIGO, Tokyo (JP)

(21) Appl. No.: 18/687,722

(22) PCT Filed: Aug. 30, 2022
(86) PCT No.: PCT/JP2022/032649

§ 371 Date: Feb. 28, 2024

(30) Foreign Application Priority Data
Aug. 31, 2021 (JP) 2021-140616

(51) Int. Cl. G03F 7/11; C08G 65/38; C08G 73/02; G03F 7/16

(52) U.S. Cl. CPC G03F 7/11; C08G 65/38; C08G 73/0273; G03F 7/161; G03F 7/162

(57) ABSTRACT

A composition for spin-on carbon film formation, that is a composition for forming a spin-on carbon film as an underlayer film for lithography, containing
a dendritic polymer.

### TECHNICAL FIELD

The present invention relates to a composition for spin-on carbon film formation, a method for producing the composition for spin-on carbon film formation, an underlayer film for lithography, a resist pattern formation method, and a circuit pattern formation method.

### BACKGROUND ART

In the production of semiconductor devices, fine processing is practiced by lithography using photoresist materials. In recent years, further miniaturization based on pattern rules has been demanded along with increase in the integration and speed of LSI (large scale integrated circuits). The light source for lithography used upon forming resist patterns has been shifted to ArF excimer laser (wavelength 193 nm) having a shorter wavelength from KrF excimer laser (wavelength 248 nm). The introduction of extreme ultraviolet light (EUV; wavelength 13.5 nm) is also expected.

As the miniaturization of resist patterns proceeds, the problem of resolution or the problem of collapse of resist patterns after development arises. Therefore, thinner resist films have been desired. However, if resist films are merely made thinner, it is difficult to obtain resist patterns with sufficient film thicknesses for substrate processing. Therefore, there has been a need for a process of preparing an underlayer film between a resist and a semiconductor substrate to be processed, and imparting, also to this underlayer film, functions as a mask for substrate processing in addition to a resist pattern. Conventional underlayer films have the function of making the resist pattern shape better by the antireflection function and by suppressing the collapse of resist patterns. As such conventional underlayer films, materials with a high etching rate have been used from the viewpoint of easy removal. On the other hand, in a process that requires the underlayer film to have a function as a mask for substrate processing, underlayer films with a small etching rate selectivity are used, as is the case for resists. Such underlayer films are also referred to as “spin-on carbon films”.

Various underlayer films for such lithography are currently known. For example, an underlayer film forming material for a multilayer resist process containing a resin component having at least a substituent that generates a sulfonic acid residue by eliminating a terminal group under application of predetermined energy, and a solvent has been suggested (see, for example, Patent Literature 1). Also, in order to realize an underlayer film for lithography having a dry etching rate selectivity smaller than that of resists, an underlayer film material containing a polymer having a specific repeat unit has been suggested (see, for example, Patent Literature 2). Furthermore, in order to realize an underlayer film for lithography having a dry etching rate selectivity smaller than that of semiconductor substrates, a resist underlayer film material containing a polymer prepared by copolymerizing a repeat unit of an acenaphthylene and a repeat unit having a substituted or unsubstituted hydroxy group has been suggested (see, for example, Patent Literature 3).

### CITATION LIST

### Patent Literature

Patent Literature 1: Japanese Patent Laid-Open No. 2004-177668
Patent Literature 2: Japanese Patent Laid-Open No. 2004-271838
Patent Literature 3: Japanese Patent Laid-Open No. 2005-250434

### SUMMARY OF INVENTION

### Technical Problem

There is still room for improvement in the film forming materials for lithography described in Patent Literatures 1 to 3 from the viewpoint of providing excellent storage stability, thin film formability, etching resistance, embedding properties, and flatness, as well as imparting a good resist pattern shape.

The present invention has been made in view of the above problems, and an object thereof is to provide a composition for spin-on carbon film formation and the like that have excellent storage stability, thin film formability, etching resistance, embedding properties, and flatness, and that can impart a good resist pattern shape.

### Solution to Problem

The present inventors have, as a result of devoted examinations to solve the above problems, found out that use of a dendritic polymer can solve the above problems, leading to completion of the present invention.

That is, the present invention is as follows.

[1]

A composition for spin-on carbon film formation, that is a composition for forming a spin-on carbon film as an underlayer film for lithography, comprising a dendritic polymer.

[2]

The composition for spin-on carbon film formation according to [1], wherein the dendritic polymer has an ester bond, a ketone bond, an amide bond, an imide bond, a urea bond, a urethane bond, an ether bond, a thioether bond, an imino bond, and/or an azomethine bond in a molecule.

[3]

The composition for spin-on carbon film formation according to [1] or [2], wherein the dendritic polymer has a chemical structure represented by the following formula (1) in a molecule:

R(R′)C═N— (1)

wherein R and R′ each independently represent an arylene group optionally having a substituent.
[4]

The composition for spin-on carbon film formation according to any of [1] to [3], wherein the dendritic polymer has an initial thermal decomposition temperature of 300° C. or higher.

[5]

The composition for spin-on carbon film formation according to any of [1] to [4], wherein the dendritic polymer has a solubility in a semiconductor coating solvent of 0.5% by mass or more.

[6]

The composition for spin-on carbon film formation according to any of [1] to [5], wherein the dendritic polymer has a carbon content of 70% or more, and/or the dendritic polymer has an oxygen content of less than 20%.

[7]

The composition for spin-on carbon film formation according to any of [1] to [6], further comprising a solvent.

[8]

The composition for spin-on carbon film formation according to any of [1] to [7], further comprising at least one selected from the group consisting of an acid generating agent and a crosslinking agent.

[9]

An underlayer film for lithography comprising the composition for spin-on carbon film formation according to any of [1] to [8],
wherein an etching rate is 60 nm/min or less, the etching rate being measured by the following method:

### <Measurement of Etching Rate>

the underlayer film for lithography is subjected to the following etching test to measure the etching rate:

### (Etching Test)

Output: 100 W
Pressure: 8 Pa
Etching gas: CF₄ gas (flow rate 20 (sccm)).
   [10]

A resist pattern formation method, comprising:
an underlayer film formation step of forming an underlayer film on a substrate using the composition for spin-on carbon film formation according to any of [1] to [8];
a photoresist layer formation step of forming at least one photoresist layer on the underlayer film formed through the underlayer film formation step; and
a step of irradiating a predetermined region of the photoresist layer formed through the photoresist layer formation step with radiation for development.
   [11]

A circuit pattern formation method, comprising:
an underlayer film formation step of forming an underlayer film on a substrate using the composition for spin-on carbon film formation according to any of [1] to [8];
an intermediate layer film formation step of forming an intermediate layer film on the underlayer film formed through the underlayer film formation step;
a photoresist layer formation step of forming at least one photoresist layer on the intermediate layer film formed through the intermediate layer film formation step;
a resist pattern formation step of irradiating a predetermined region of the photoresist layer formed through the photoresist layer formation step with radiation for development, thereby forming a resist pattern;
an intermediate layer film pattern formation step of etching the intermediate layer film with the resist pattern formed through the resist pattern formation step as a mask, thereby forming an intermediate layer film pattern;
an underlayer film pattern formation step of etching the underlayer film with the intermediate layer film pattern formed through the intermediate layer film pattern formation step as a mask, thereby forming an underlayer film pattern; and
a substrate pattern formation step of etching the substrate with the underlayer film pattern formed through the underlayer film pattern formation step as a mask, thereby forming a pattern on the substrate.
   [12]

A method for producing the composition for spin-on carbon film formation according to any of [1] to [8], comprising
an extraction step of bringing a solution comprising the dendritic polymer and an organic solvent that does not inadvertently mix with water into contact with an acidic aqueous solution, thereby carrying out extraction.
   [13]

A method for producing the composition for spin-on carbon film formation according to any of [1] to [8], comprising a step of passing a solution in which the dendritic polymer is dissolved in a solvent through a filter.

[14]

A method for producing the composition for spin-on carbon film formation according to any of [1] to [8], comprising a step of bringing a solution in which the dendritic polymer is dissolved in a solvent into contact with an ion exchange resin.

### Advantageous Effects of Invention

The present invention can provide a composition for spin-on carbon film formation and the like that have excellent storage stability, thin film formability, etching resistance, embedding properties, and flatness, and that can impart a good resist pattern shape.

### DESCRIPTION OF EMBODIMENTS

Hereinafter, an embodiment for carrying out the present invention (hereinafter, also denoted as “present embodiment”) will be described in detail. The present embodiment described below is only illustrative of the present invention and is not intended to limit the present invention to the contents of the following description. The present invention can be carried out with appropriate modifications falling within the gist of the invention.

### <Composition for Spin-On Carbon Film Formation>

A composition for spin-on carbon film formation of the present embodiment is a composition for forming a spin-on carbon film as an underlayer film for lithography, and contains a dendritic polymer. Since the composition for spin-on carbon film formation of the present embodiment is constituted as described above, it has excellent storage stability, thin film formability, etching resistance, embedding properties, and flatness, and can impart a good resist pattern shape.

In the present embodiment, the spin-on carbon film means a functional film that is a carbon-rich film formed by the spin coating method and has resistance to etching, and the composition for spin-on carbon film formation means a composition used for applications for forming the spin-on carbon film. The dendritic polymer, which will be described in detail later, is suitable for the above applications since it can achieve, by virtue of its structure, a high density when forming a film. The spin-on carbon film according to the present embodiment is used as an underlayer film for lithography. Being a spin-on carbon film can typically be confirmed by an etching rate of 60 nm/min or less, the etching rate being measured in the etching rate measurement described later, or by other means, although the method is not limited to this. It is preferable that the spin-on carbon film according to the present embodiment has excellent embedding properties to a substrate having difference in level, as well as excellent film flatness.

### [Dendritic Polymer]

The dendritic polymer means a polymer that has a branched structure in the polymer chain and that is constituted by a molecular structure in which frequent and regular branches are repeated. In the dendritic polymer, the branched structure makes it a nano-sized functional polymer. Also, the dendritic polymer tends to have repeated branched structures, resulting in a sterically crowded skeleton, which leads to a structure in which atoms are concentrated in a high density. As such, the dendritic polymer tends to be a high-density polymer film by virtue of its structure, resulting in a carbon-rich film, which can be used as an underlayer film for lithography to impart high etching resistance.

The dendritic polymer is not particularly limited, and for example, those described in “Dendritic Macromolecules” (The Society of Polymer Science, Japan, Kyoritsu Shuppan Co., Ltd. (2013)) can be employed. The dendritic polymer can be characterized by the number of terminal groups. General linear polymers have two terminal groups and a degree of branching of 0, whereas dendritic polymers typically tend to have three or more terminal groups and a degree of branching of 1 or more.

As a concept for the degree of polymerization of dendritic polymers, “generation” is used in some cases. Those with one layer of molecules having terminal groups bonded around the core, which will be described later, are called “first generation” and those with two layers bonded are called “second generation”. Dendritic polymers may have a structure identified as one or more layers of molecules having terminal groups bonded around the core. The dendritic polymer used in the present embodiment is not particularly limited, and the fifth or lower generation is preferred from the viewpoint of solubility and flatness, and the fourth or lower generation is still more preferred.

As the dendritic polymer, typically, various dendritic polymers may be employed that are publicly known as dendrimers, hyperbranched polymers, star polymers, polymer brushes, and the like. The dendritic polymer can be used alone as one kind, or can be used in combination of two or more kinds.

In the present embodiment, a dendrimer is preferred from the viewpoint of stability of various physical properties, a hyperbranched polymer is preferred from the viewpoint of ease of production, and appropriate selection can be made for use depending on the required performance.

As the dendrimer that can be used as the dendritic polymer in the present embodiment, various publicly known dendrimers can be employed, including, but not limited to, those described as dendrimers in Japanese Patent Laid-Open No. 2000-344836, Japanese Patent Laid-Open No. 2004-331850, Japanese Patent Laid-Open No. 2009-029753, Japanese Patent Laid-Open No. 2008-088275, and Japanese Patent Laid-Open No. 10-310545, for example.

As the hyperbranched polymer that can be used as the dendritic polymer in the present embodiment, various publicly known hyperbranched polymers can be employed, including, but not limited to, those described as hyperbranched polymers in Japanese Patent Laid-Open No. 2000-344836, International Publication No. WO 2006-25236, International Publication No. WO 2012-60286, and International Publication No. WO 2015-87969, for example.

The dendritic polymer may have, for example, but not limited to, a di- or higher-valent core having 2 to 100 carbon atoms, and the core may contain an arylene group (an organic group derived from an aromatic compound such as a benzene ring, a biphenyl ring, a naphthalene ring, an anthracene ring, a pyrene ring, a dibenzo chrysene ring, and a fluorene ring). Note that such an organic group may have a substituent. The above substituent is not particularly limited, and from the viewpoint of solubility, a hydroxy group, a thiol group, a sulfonic acid group, a hexafluoropropanol group, an amino group, or a carboxyl group is preferred. The core may also contain a heteroatom, preferably a triazine group.

The number of carbon atoms in the core is preferably 2 to 80 from the viewpoint of ensuring various physical properties, more preferably 2 to 60 from the viewpoint of storage stability, still more preferably 2 to 40 from the viewpoint of thin film formability, and even more preferably 2 to 20 from the viewpoint of solubility.

The dendritic polymer may contain the structures described above as those that may be contained in the core, but in a portion other than the core.

Besides, the dendritic polymer may contain an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, and/or a hydroxy group, and may contain an alkylene group, alkenylene group, and/or alkynylene group having 1 to 40 carbon atoms and optionally having a substituent. Furthermore, the dendritic polymer may contain an ester bond, a ketone bond, an amide bond, an imide bond, a urea bond, a urethane bond, an ether bond, a thioether bond, an imino bond, and/or an azomethine bond.

The dendritic polymer may contain one of the functional groups and bonds described above alone, or may contain two or more of them.

In the present embodiment, the dendritic polymer preferably has an alkylene group, an alkenylene group, an alkynylene group, an ester bond, a ketone bond, an amide bond, an imide bond, a urea bond, a urethane bond, an ether bond, a thioether bond, an imino bond, and/or an azomethine bond in its molecule from the viewpoint of heat resistance, more preferably has an ester bond, a ketone bond, an amide bond, an imide bond, a urea bond, a urethane bond, an ether bond, a thioether bond, an imino bond, and/or an azomethine bond from the viewpoint of storage stability, particularly preferably has an imino bond and/or an azomethine bond from the viewpoint of etching resistance, and still more preferably has an azomethine bond from the viewpoint of further improving heat resistance, storage stability, thin film formability, etching resistance, embedding properties, and flatness, as well as imparting a better resist pattern shape.

In the present embodiment, from the viewpoint of storage stability, it is preferable that the dendritic polymer does not contain an ethynyl group in its molecule.

Also, in the present embodiment, from the viewpoint of further improving heat resistance, storage stability, thin film formability, etching resistance, embedding properties, and flatness, as well as imparting a better resist pattern shape, it is preferable that the dendritic polymer does not contain an alicycle in its molecule.

In the present embodiment, the dendritic polymer preferably has, as a terminal group, an organic group derived from an aromatic compound such as a benzene ring, a biphenyl ring, a naphthalene ring, an anthracene ring, a pyrene ring, a dibenzo chrysene ring, and a fluorene ring, or a dissociable group or crosslinking group, and they may have a substituent. Such a substituent is preferably a hydroxy group, a thiol group, a sulfonic acid group, a hexafluoropropanol group, an amino group, or a carboxyl group from the viewpoint of solubility. In the present embodiment, it is more preferable that the dendritic polymer has a phenolic hydroxy group or a dissociable group as a terminal group.

In the present embodiment, from the viewpoint of further improving heat resistance, storage stability, thin film formability, etching resistance, embedding properties, and flatness, as well as imparting a better resist pattern shape, it is preferable that the dendritic polymer has the chemical structure represented by the following formula (1) in the molecule.

R(R′)C═N— (1)

(wherein R and R′ each independently represent an arylene group optionally having a substituent.)

The arylene group in the above formula (1) is not particularly limited, and examples thereof include a phenylene group optionally having a substituent, a biphenylene group optionally having a substituent, a naphthylene group optionally having a substituent, an anthracenylene group optionally having a substituent, a pyrenylene group optionally having a substituent, and a fluorenylene group optionally having a substituent. The above substituent is not particularly limited, and from the viewpoint of solubility, a hydroxy group, a thiol group, a sulfonic acid group, a hexafluoropropanol group, an amino group, or a carboxyl group is preferred. In the present embodiment, from the viewpoint of further improving heat resistance, storage stability, thin film formability, etching resistance, embedding properties, and flatness, as well as imparting a better resist pattern shape, R and R′ are each independently preferably an arylene group having —OH, —O—C(═O)—CH₃, or —O—CH₂—O—CH₃ as a substituent, and more preferably a phenylene group having —OH, —O—C(═O)—CH₃, or —O—CH₂—O—CH₃ as a substituent.

Specific examples of the structure that may be contained in the dendritic polymer include, but are not limited to, the following divalent groups, or combinations thereof, which may have a substituent.

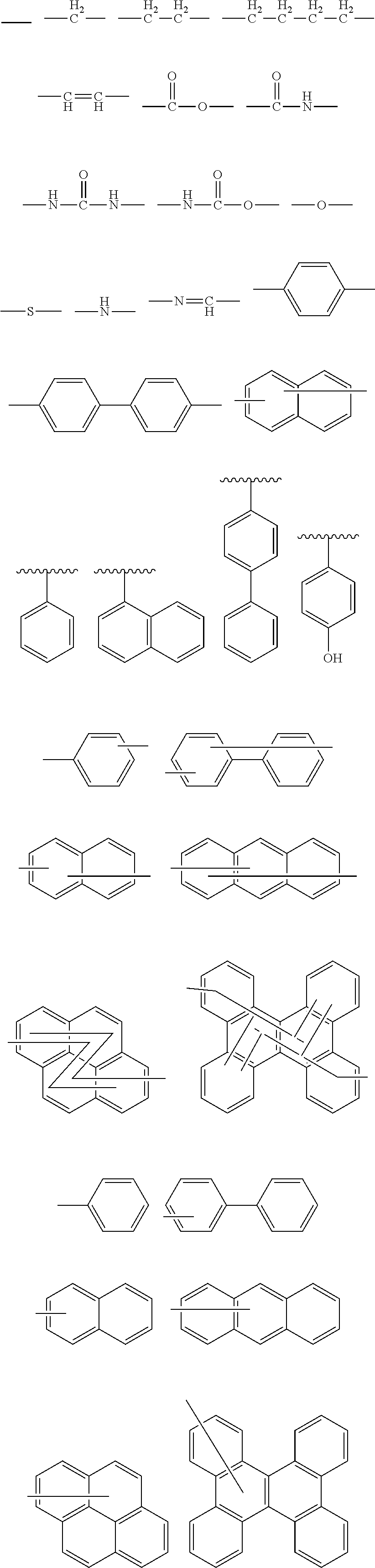

In the present embodiment, “substitution” means that at least one of the hydrogen atoms bonded to carbon atoms constituting an aromatic ring and hydrogen atoms in certain functional groups is substituted with a substituent, unless otherwise defined.

Unless otherwise defined, examples of the “substituent” include a halogen atom, a hydroxy group, a carboxyl group, a cyano group, a nitro group, a thiol group, a heterocyclic group, an alkyl group having 1 to 30 carbon atoms, an aryl group having 6 to 20 carbon atoms, an alkoxyl group having 1 to 30 carbon atoms, an alkenyl group having 2 to 30 carbon atoms, an alkynyl group having 2 to 30 carbon atoms, an acyl group having 1 to 30 carbon atoms, and an amino group having 0 to 30 carbon atoms.

In the present embodiment, the “alkyl group” may be in any aspect of a linear aliphatic hydrocarbon group, a branched aliphatic hydrocarbon group, and a cyclic aliphatic hydrocarbon group, unless otherwise defined.

The “dissociable group” in the present embodiment refers to a group that dissociates in the presence of a catalyst or without a catalyst. Among dissociable groups, the acid dissociable group refers to a group that is cleaved in the presence of an acid to cause a change into an alkali soluble group or the like.

Examples of the alkali soluble group include, but are not particularly limited to, a phenolic hydroxy group, a carboxyl group, a sulfonic acid group, and a hexafluoroisopropanol group. Among them, a phenolic hydroxy group and a carboxyl group are preferred, and a phenolic hydroxy group is more preferred, from the viewpoint of easy availability of an introduction reagent.

It is preferable that the acid dissociable group has the property of causing chained cleavage reaction in the presence of an acid, for achieving pattern formation with high sensitivity and high resolution.

The acid dissociable group is not particularly limited, and can be selected for use as appropriate from among, for example, those proposed in hydroxystyrene resins, (meth)acrylic acid resins, and the like for use in chemically amplified resist compositions for KrF or ArF.

Specific examples of the acid dissociable group include those described in International Publication No. WO 2016/158168. Suitable examples of the acid dissociable group include a 1-substituted ethyl group, a 1-substituted n-propyl group, a 1-branched alkyl group, a silyl group, an acyl group, a 1-substituted alkoxymethyl group, a cyclic ether group, an alkoxycarbonyl group, and an alkoxycarbonylalkyl group, which has the property of being dissociated by an acid.

The “crosslinkable group” in the present embodiment refers to a group that crosslinks in the presence of a catalyst or without a catalyst. Examples of the crosslinkable group include, but are not particularly limited to, an alkoxy group having 1 to 20 carbon atoms, a group having an allyl group, a group having a (meth)acryloyl group, a group having an epoxy (meth)acryloyl group, a group having a hydroxy group, a group having a urethane (meth)acryloyl group, a group having a glycidyl group, a group having a vinyl-containing phenylmethyl group, a group having a group having various alkynyl groups, a group having a carbon-carbon double bond, a group having a carbon-carbon triple bond, and a group containing these groups. Suitable examples of the above group containing these groups include an alkoxy group of the above groups —ORx (Rx is a group having an allyl group, a group having a (meth)acryloyl group, a group having an epoxy (meth)acryloyl group, a group having a hydroxy group, a group having a urethane (meth)acryloyl group, a group having a glycidyl group, a group having a vinyl-containing phenylmethyl group, a group having a group having various alkynyl groups, a group having a carbon-carbon double bond, a group having a carbon-carbon triple bond, and a group containing these groups).

As the dendritic polymer in the present embodiment, the following compounds can be used, for example, but it is not limited to them.

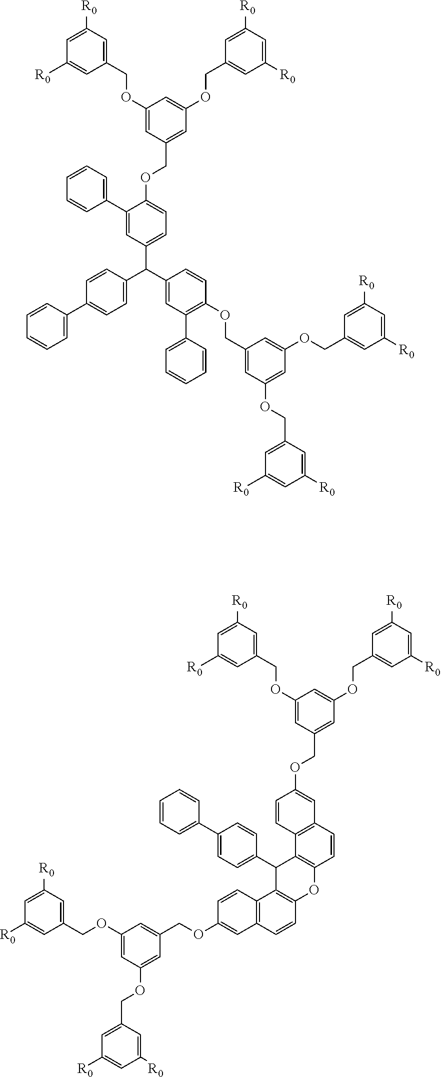

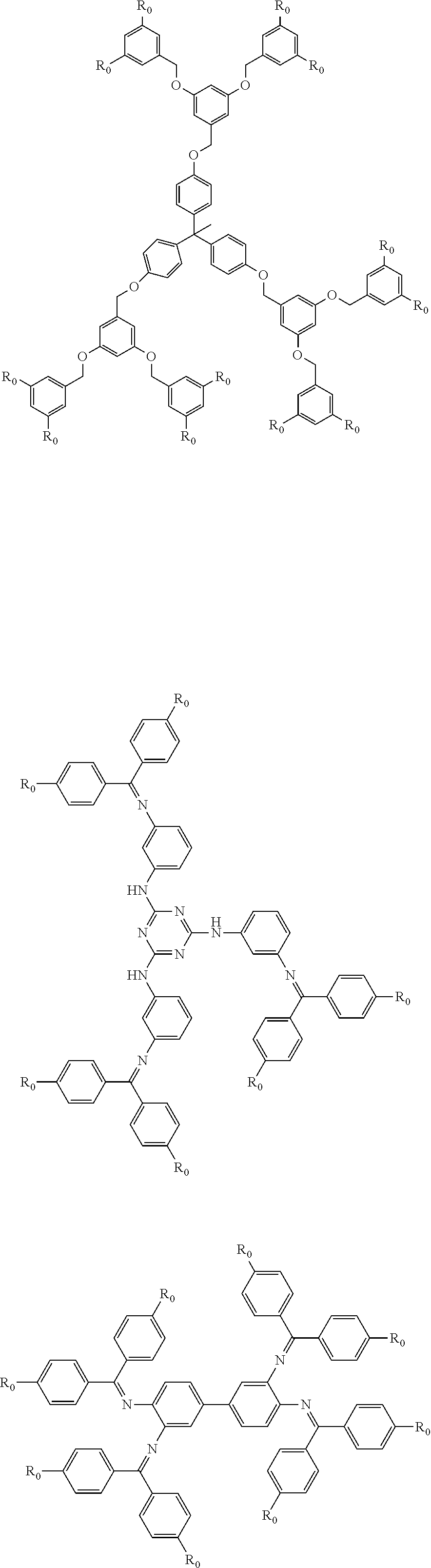

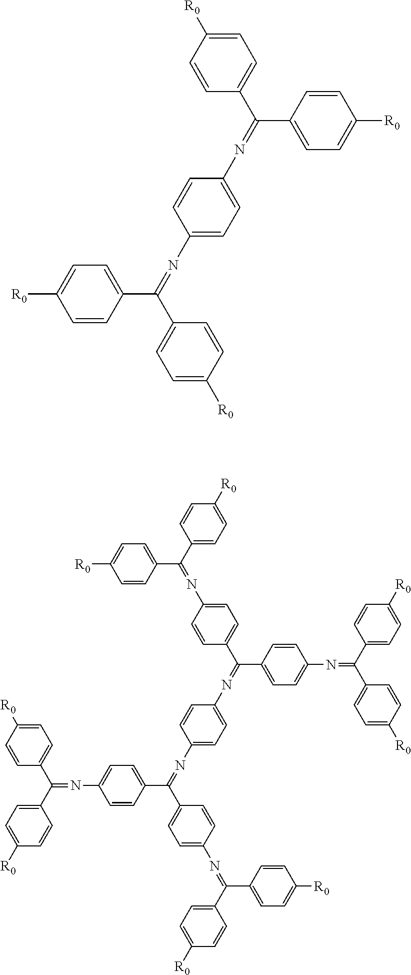

(wherein R₀ is a hydroxy group, an alkoxy group, a thiol group, a sulfonic acid group, a hexafluoropropanol group, an amino group or a carboxyl group, or a group in which a hydrogen atom thereof is substituted with a dissociable group or a crosslinking group, and it is preferable that at least one R₀ is a hydroxy group and it is more preferable that all of R₀ are hydroxy groups.)

As the dendritic polymer in the present embodiment, the following compounds can also be used, for example, but it is not limited to them.

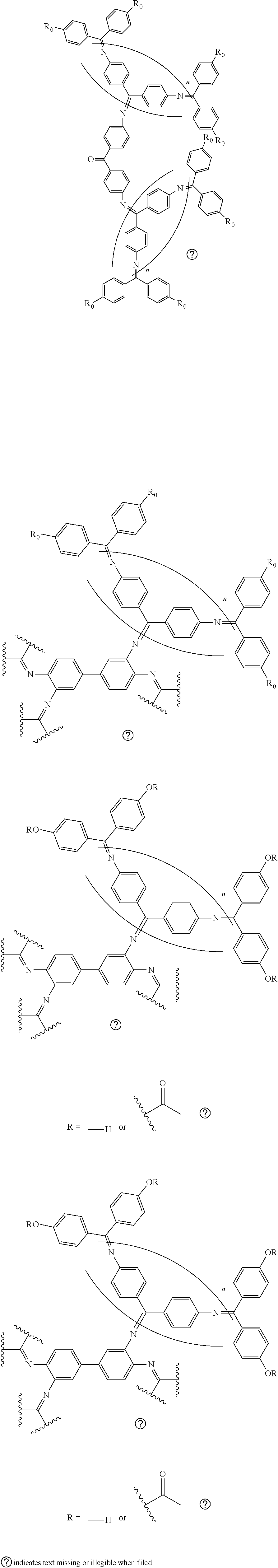

(wherein R₀ is a hydroxy group, an alkoxy group, a thiol group, a sulfonic acid group, a hexafluoropropanol group, an amino group or a carboxyl group, or a group in which a hydrogen atom thereof is substituted with a dissociable group or a crosslinking group, and it is preferable that at least one R₀ is a hydroxy group, and it is more preferable that all of R₀ are hydroxy groups.)

The method for producing the dendritic polymer in the present embodiment is not particularly limited, and it can be synthesized by various publicly known methods. As the dendritic polymer, commercially available products can also be employed.

In the present embodiment, from the viewpoint of heat resistance, the initial thermal decomposition temperature of the dendritic polymer is preferably 300° C. or higher, more preferably 350° C. or higher, still more preferably 400° C. or higher, even more preferably 450° C. or higher, and still further preferably 500° C. or higher.

The initial thermal decomposition temperature can be measured based on the method described in Examples, which will be described later.

The initial thermal decomposition temperature can be adjusted to the above range by, for example, selecting the raw materials of the dendritic polymer as appropriate so that it has the preferred chemical structure as described above, or by adjusting the carbon content and/or oxygen content to the preferred range as described later.

In the present embodiment, from the viewpoint of easier application to a wet process, etc., the solubility of the dendritic polymer in the semiconductor coating solvent is preferably 0.5% by mass or more, more preferably 1% by mass or more, still more preferably 5% by mass or more, and even more preferably 10% by mass or more. In the present embodiment, the semiconductor coating solvent means propylene glycol monomethyl ether (PGME), propylene glycol monomethyl ether acetate (PGMEA), cyclohexanone (CHN), cyclopentanone (CPN), ethyl lactate (EL), and methyl hydroxyisobutyrate (HBM).

The solubility can be measured based on the method described in Examples, which will be described later.

The solubility can be adjusted to the above range by, for example, selecting the raw materials of the dendritic polymer as appropriate so that it has the preferred chemical structure as described above, or by controlling the molecular weight to the preferred range as described later.

In the present embodiment, from the viewpoint of etching resistance, it is preferable that the carbon content of the dendritic polymer is 70% or more and/or the oxygen content of the dendritic polymer is less than 20%, and it is preferable that at least the oxygen content of the dendritic polymer is less than 20%. More specifically, from the viewpoint of etching resistance, the carbon content of the dendritic polymer is preferably 70% or more, more preferably 75% or more, still more preferably 80% or more, and particularly preferably 85% or more. From the same viewpoint, the oxygen content is preferably less than 20%, more preferably less than 17.5%, still more preferably less than 15%, and particularly preferably less than 10%.

The carbon content and the oxygen content can be measured based on the method described in Examples, which will be described later.

The carbon content and the oxygen content can be adjusted to the above ranges by, for example, selecting the raw materials of the dendritic polymer as appropriate so that it has the preferred chemical structure as described above.

The dendritic polymer may be subjected to a treatment such as high-temperature baking or reactions with other compounds so that the resulting carbon content and/or oxygen content are in the above ranges.

In the present embodiment, the dendritic polymer has a Si content and/or a F content of less than 1%, and the Si content and/or the F content are preferably 0%. In the case where Si or F is contained in the dendritic polymer, etching resistance tends to be significantly reduced under chlorofluorocarbon-based gas conditions, which are suitable for processing of inorganic materials such as silicon wafers, and a Si content and/or a F content of less than 1% tends to ensure sufficient etching resistance even under the conditions described later in (Etching Test), for example.

In the present embodiment, from the viewpoint of heat resistance, the molecular weight of the dendritic polymer is preferably 400 to 1000000, more preferably 800 to 50000, and from the viewpoint of resolution, still more preferably 1200 to 10000. In the case where the molecular weight of the dendritic polymer is 1200 or more, the molecule tends to be close to a spherical shape and can form a dense film, which is thought to improve the resolution, although this is not intended to limit the mechanism of action to the above. Also, from the viewpoint of flatness, it is preferably 350 to 5000, more preferably 500 to 3000, and still more preferably 950 to 2000.

The molecular weight can be measured by liquid chromatography-mass spectrometry (LC-MS) for those smaller than about 2000, and can be measured by gel permeation chromatography (GPC) analysis for those with larger molecular weights. Specifically, it can be measured based on the method described in Examples, which will be described later.

In the present embodiment, in the case where hydroxy groups are contained in the molecule of the dendritic polymer, at least one of them may be protected by a protecting group. It is preferable for the composition for spin-on carbon film formation of the present embodiment to contain a dendritic polymer having at least one hydroxy group in the molecule and a dendritic polymer in which at least one of the hydroxy groups in the molecule is protected by a protecting group. In this case, a film containing a protected body and an unprotected body is formed, which is thought to improve adhesive force with the resist film and tend to suppress pattern collapse and distortion, although this is not intended to limit the mechanism of action to the above. The protecting group is not particularly limited and various publicly known protecting groups can be employed, but from the same viewpoint as described above, it is preferably —CH₂OCH₃.

### [Additional Component]

The composition for spin-on carbon film formation of the present embodiment contains the dendritic polymer according to the present embodiment as an essential component, and may further contain any of various optional components in consideration of use as an underlayer film forming material for lithography. Specifically, it is preferable that the composition for spin-on carbon film formation of the present embodiment further contains at least one selected from the group consisting of a solvent, an acid generating agent, and a crosslinking agent.

The content of the dendritic polymer according to the present embodiment in the composition for spin-on carbon film formation of the present embodiment is preferably 1 to 100% by mass, more preferably 10 to 100% by mass, still more preferably 50 to 100% by mass, and particularly preferably 100% by mass based on the total solid content (components other than the solvent in the composition for spin-on carbon film formation of the present embodiment), from the viewpoint of coatability and quality stability.

When the composition for spin-on carbon film formation of the present embodiment contains a solvent, the content of the dendritic polymer according to the present embodiment is not particularly limited, and is preferably 0.5 to 33 parts by mass, more preferably 0.5 to 25 parts by mass, and still more preferably 0.5 to 20 parts by mass based on 100 parts by mass in total including the solvent.

The composition for spin-on carbon film formation of the present embodiment is applicable to a wet process and is excellent in heat resistance and etching resistance. Furthermore, the composition for spin-on carbon film formation of the present embodiment contains the dendritic polymer according to the present embodiment and can therefore form an underlayer film that is prevented from deteriorating upon baking at a high temperature and is also excellent in etching resistance against oxygen plasma etching or the like. Moreover, the composition for spin-on carbon film formation of the present embodiment is also excellent in adhesiveness to a resist layer and can therefore obtain an excellent resist pattern. The composition for spin-on carbon film formation of the present embodiment may contain an already known underlayer film forming material for lithography or the like, within the range not deteriorating the desired effects of the present embodiment.

### (Solvent)

Any publicly known solvent can be appropriately used as the solvent used in the composition for spin-on carbon film formation of the present embodiment as long as at least the dendritic polymer of the present embodiment dissolves.

Specific examples of the solvent include, but are not particularly limited to, those described in International Publication No. WO 2013/024779. These solvents can be used alone as one kind, or can be used in combination of two or more kinds.

Among the above solvents, cyclohexanone, propylene glycol monomethyl ether, propylene glycol monomethyl ether acetate, ethyl lactate, methyl hydroxyisobutyrate, or anisole is particularly preferred from the viewpoint of safety.

The content of the solvent is not particularly limited, and is preferably 100 to 30,000 parts by mass, more preferably 200 to 20,000 parts by mass, and still more preferably 250 to 15,000 parts by mass based on 100 parts by mass of the dendritic polymer according to the present embodiment, from the viewpoint of solubility and film formation.

### (Crosslinking Agent)

The composition for spin-on carbon film formation of the present embodiment may contain a crosslinking agent, if required, from the viewpoint of, for example, suppressing intermixing. The crosslinking agent that may be used in the present embodiment is not particularly limited, and those described in, for example, International Publication No. WO 2013/024778, International Publication No. WO 2013/024779, and International Publication No. WO 2018/016614 can be used. In the present embodiment, the crosslinking agent can be used alone, or can be used in combination of two or more kinds.

Specific examples of the crosslinking agent that may be used in the present embodiment include, but are not particularly limited to, a phenol compound, an epoxy compound, a cyanate compound, an amino compound, a benzoxazine compound, an acrylate compound, a melamine compound, a guanamine compound, a glycoluril compound, a urea compound, an isocyanate compound, and an azide compound. These crosslinking agents can be used alone as one kind, or can be used in combination of two or more kinds. Among these, a benzoxazine compound, an epoxy compound, or a cyanate compound is preferred, and a benzoxazine compound is more preferred from the viewpoint of improvement in etching resistance. Furthermore, a melamine compound and a urea compound are more preferred from the viewpoint of having good reactivity. Examples of the melamine compound include a compound represented by the formula (a) (NIKALAC MW-100LM (trade name), manufactured by Sanwa Chemical Co., Ltd.) and a compound represented by the formula (b) (NIKALAC MX270 (trade name), manufactured by Sanwa Chemical Co., Ltd.).

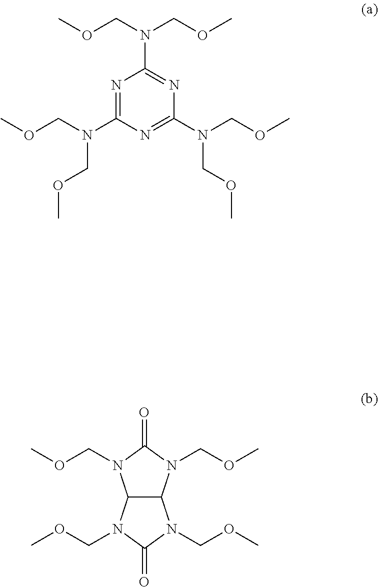

As the above phenol compound, any publicly known one can be used, and the phenol compound is not particularly limited. In the present embodiment, as the crosslinking agent, a fused aromatic ring-containing phenol compound is more preferred from the viewpoint of improving etching resistance. Also, a methylol group-containing phenol compound is more preferred from the viewpoint of improving smoothing properties.

The methylol group-containing phenol compound used as the crosslinking agent is preferably one represented by the following formula (11-1) or (11-2) from the viewpoint of improving smoothing properties.

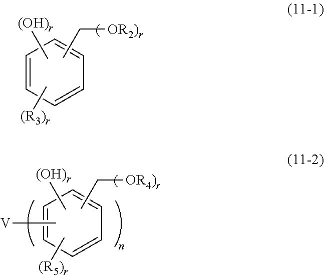

In the crosslinking agent represented by the general formula (11-1) or (11-2), V is a single bond or an n-valent organic group, R₂ and R₄ are each independently a hydrogen atom or an alkyl group having 1 to 10 carbon atoms, and R₃ and R₅ are each independently an alkyl group having 1 to 10 carbon atoms or an aryl group having 6 to 40 carbon atoms. n is an integer of 2 to 10, and r is each independently an integer of 0 to 6.

Specific examples of the general formula (11-1) or (11-2) include compounds represented by the following formulas. However, the general formula (11-1) or (11-2) is not limited to the compounds represented by the following formulas. The compounds represented by the general formulas (11-24) to (11-34) are preferred from the viewpoint of heat resistance, and the compounds represented by the general formulas (11-32) to (11-34) are more preferred since they are applicable at a higher temperature.

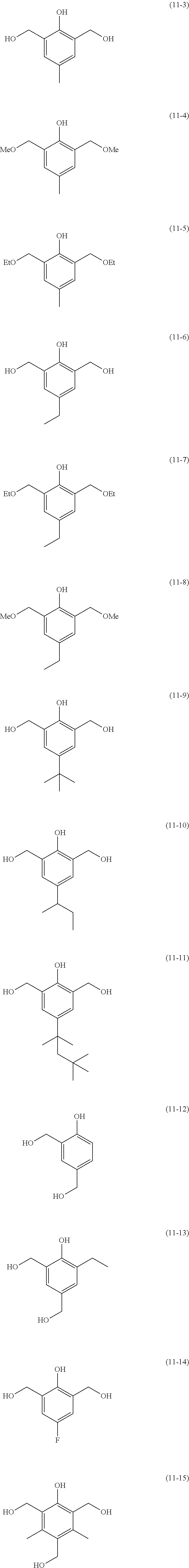

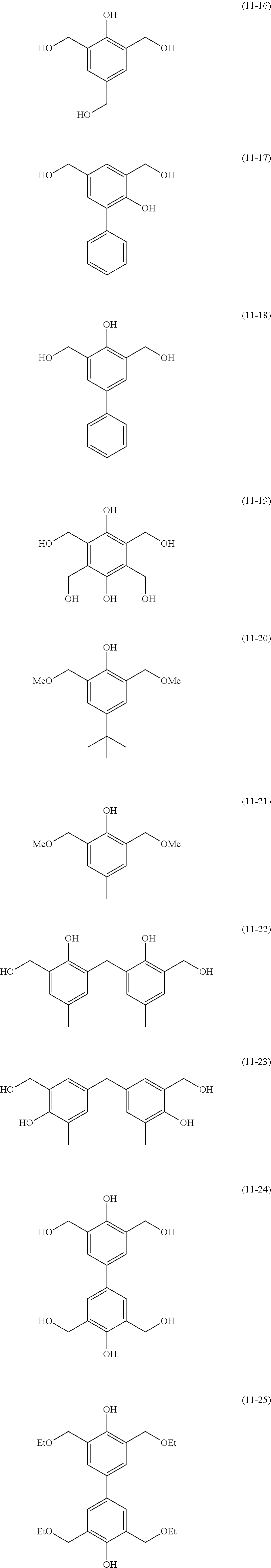

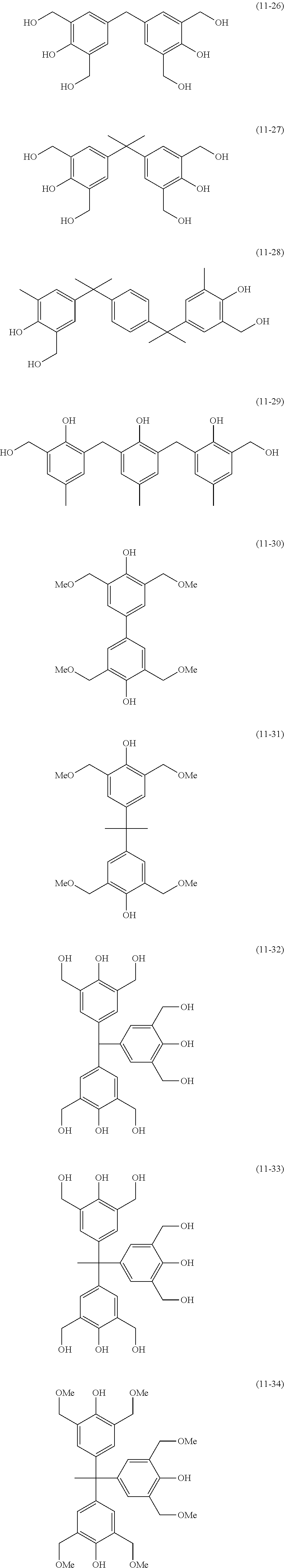

As the above epoxy compound, any publicly known one can be used, and the epoxy compound is not particularly limited. However, it is preferably an epoxy resin that is in a solid state at normal temperature, such as an epoxy resin obtained from a phenol aralkyl resin or a biphenyl aralkyl resin from the viewpoint of heat resistance and solubility.

The above cyanate compound is not particularly restricted as long as it is a compound that has two or more cyanate groups in one molecule, and any publicly known one can be used. In the present embodiment, preferred examples of the cyanate compound include those having a structure in which hydroxy groups of a compound having two or more hydroxy groups in one molecule are replaced with cyanate groups. Also, the cyanate compound is preferably a cyanate compound that has an aromatic group, and those having a structure in which a cyanate group is directly bonded to an aromatic group can be suitably used. Examples of such a cyanate compound include, but are not particularly limited to, those having a structure in which hydroxy groups of bisphenol A, bisphenol F, bisphenol M, bisphenol P, bisphenol E, a phenol novolac resin, a cresol novolac resin, a dicyclopentadiene novolac resin, tetramethylbisphenol F, a bisphenol A novolac resin, brominated bisphenol A, a brominated phenol novolac resin, trifunctional phenol, tetrafunctional phenol, naphthalene-based phenol, biphenyl-based phenol, a phenol aralkyl resin, a biphenyl aralkyl resin, a naphthol aralkyl resin, a dicyclopentadiene aralkyl resin, alicyclic phenol, phosphorus-containing phenol, or the like are replaced with cyanate groups. Also, the above cyanate compound may be in any form of a monomer, an oligomer, and a resin.

As the above amino compound, any publicly known one can be used, and the amino compound is not particularly limited. However, 4,4′-diaminodiphenylmethane, 4,4′-diaminodiphenylpropane, and 4,4′-diaminodiphenyl ether are preferred from the viewpoint of heat resistance and availability of raw materials.

As the above benzoxazine compound, any publicly known one can be used, and the benzoxazine compound is not particularly limited. However, P-d-type benzoxazine obtained from difunctional diamines and monofunctional phenols is preferred from the viewpoint of heat resistance.

As the above melamine compound, any publicly known one can be used, and the melamine compound is not particularly limited. However, a compound in which 1 to 6 methylol groups of hexamethylol melamine, hexamethoxymethyl melamine, or hexamethylol melamine are methoxymethylated or a mixture thereof is preferred from the viewpoint of availability of raw materials.

As the above guanamine compound, any publicly known one can be used, and the guanamine compound is not particularly limited. However, tetramethylolguanamine, tetramethoxymethylguanamine, a compound in which 1 to 4 methylol groups of tetramethylolguanamine are methoxymethylated, or a mixture thereof is preferred from the viewpoint of heat resistance.

As the above glycol uryl compound, any publicly known one can be used, and the glycol uryl compound is not particularly limited. However, tetramethylolglycol uryl and tetramethoxyglycol uryl are preferred from the viewpoint of heat resistance and etching resistance.

As the above urea compound, any publicly known one can be used, and the urea compound is not particularly limited. However, tetramethylurea and tetramethoxymethylurea are preferred from the viewpoint of heat resistance.

In the present embodiment, a crosslinking agent having at least one allyl group may be used from the viewpoint of improvement in crosslinkability. Among them, an allylphenol such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl)sulfide, or bis(3-allyl-4-hydroxyphenyl) ether is preferred.

In the composition for spin-on carbon film formation of the present embodiment, the content of the crosslinking agent is not particularly limited, and is preferably 5 to 50 parts by mass, and more preferably 10 to 40 parts by mass based on 100 parts by mass of the dendritic polymer according to the present embodiment. By setting the content of the crosslinking agent to the above preferred range, occurrence of a mixing event with a resist layer tends to be prevented. Also, an antireflection effect is enhanced, and film formability after crosslinking tends to be enhanced.

### (Crosslinking Promoting Agent)

In the composition for spin-on carbon film formation of the present embodiment, if required, a crosslinking promoting agent for accelerating crosslinking or curing reaction can be used.

The above crosslinking promoting agent is not particularly limited as long as it accelerates crosslinking or curing reaction, and examples thereof include an amine, an imidazole, an organic phosphine, and a Lewis acid. These crosslinking promoting agents can be used alone as one kind, or can be used in combination of two or more kinds. Among these, an imidazole or an organic phosphine is preferred, and an imidazole is more preferred from the viewpoint of decrease in crosslinking temperature.

As the above crosslinking promoting agent, any publicly known one can be used, and the crosslinking promoting agent is not particularly limited. However, examples thereof include those described in International Publication No. WO 2018/016614. From the viewpoint of heat resistance and acceleration of curing, 2-methylimidazole, 2-phenylimidazole, and 2-ethyl-4-methylimidazole are particularly preferred.

The content of the crosslinking promoting agent is usually preferably 0.1 to 10 parts by mass based on 100 parts by mass of the total mass of the composition, and is more preferably 0.1 to 5 parts by mass from the viewpoint of easy control and cost efficiency, and still more preferably 0.1 to 3 parts by mass.

### (Radical Polymerization Initiator)

The composition for spin-on carbon film formation of the present embodiment can contain, if required, a radical polymerization initiator. The radical polymerization initiator may be a photopolymerization initiator, which initiates radical polymerization by light, or may be a thermal polymerization initiator, which initiates radical polymerization by heat. The radical polymerization initiator can be at least one selected from the group consisting of a ketone-based photopolymerization initiator, an organic peroxide-based polymerization initiator, and an azo-based polymerization initiator.

Such a radical polymerization initiator is not particularly restricted, and a radical polymerization initiator conventionally used can be employed as appropriate. For example, examples thereof include those described in International Publication No. WO 2018/016614. Among these, dicumyl peroxide, 2,5-dimethyl-2,5-bis(t-butylperoxy)hexane, and t-butylcumyl peroxide are particularly preferred from the viewpoint of availability of raw materials and storage stability.

As the radical polymerization initiator used for the present embodiment, one kind thereof may be used alone, or two or more kinds may be used in combination. Alternatively, the radical polymerization initiator according to the present embodiment may be used in further combination with an additional publicly known polymerization initiator.

### (Acid Generating Agent)

The composition for spin-on carbon film formation of the present embodiment may contain an acid generating agent, if required, from the viewpoint of, for example, further accelerating crosslinking reaction by heat. An acid generating agent that generates an acid by thermal decomposition, an acid generating agent that generates an acid by light irradiation, and the like are known, any of which can be used.

The acid generating agent is not particularly limited, and, for example, those described in International Publication No. WO 2013/024779 can be used. In the present embodiment, the acid generating agent can be used alone or can be used in combination of two or more kinds.

In the composition for spin-on carbon film formation of the present embodiment, the content of the acid generating agent is not particularly limited, and is preferably 0.1 to 50 parts by mass, and more preferably 0.5 to 40 parts by mass based on 100 parts by mass of the polymer according to the present embodiment. By setting the content of the acid generating agent to the above preferred range, crosslinking reaction tends to be enhanced by an increased amount of an acid generated. Also, occurrence of a mixing event with a resist layer tends to be prevented.

### (Basic Compound)

The composition for spin-on carbon film formation of the present embodiment may further contain a basic compound from the viewpoint of, for example, improving storage stability.

The basic compound plays a role as a quencher against acids in order to prevent crosslinking reaction from proceeding due to a trace amount of an acid generated by the acid generating agent. Examples of such a basic compound include, but are not particularly limited to, a primary, secondary, or tertiary aliphatic amine, an amine blend, an aromatic amine, a heterocyclic amine, a nitrogen-containing compound having a carboxy group, a nitrogen-containing compound having a sulfonyl group, a nitrogen-containing compound having a hydroxy group, a nitrogen-containing compound having a hydroxyphenyl group, an alcoholic nitrogen-containing compound, an amide derivative, and an imide derivative.

The basic compound used in the present embodiment is not particularly limited, and, for example, those described in International Publication No. WO 2013/024779 can be used. In the present embodiment, the basic compound can be used alone or can be used in combination of two or more kinds.

In the composition for spin-on carbon film formation of the present embodiment, the content of the basic compound is not particularly limited, and is preferably 0.001 to 2 parts by mass, and more preferably 0.01 to 1 part by mass based on 100 parts by mass of the dendritic polymer according to the present embodiment. By setting the content of the basic compound to the above preferred range, storage stability tends to be enhanced without excessively deteriorating crosslinking reaction.

### (Additional Additive Agent)

The composition for spin-on carbon film formation of the present embodiment may also contain an additional resin and/or compound for the purpose of conferring thermosetting properties or controlling absorbance. Examples of such an additional resin and/or compound include, but are not particularly limited to, a naphthol resin, a xylene resin, a naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin not containing an aromatic ring; and a resin or compound containing an alicyclic structure, such as a rosin-based resin, a cyclodextrin, an adamantine(poly)ol, a tricyclodecane(poly)ol, and a derivative thereof. Base materials applied as resists for g-ray, i-ray, KrF excimer laser (248 nm), ArF excimer laser (193 nm), extreme ultraviolet (EUV) lithography (13.5 nm), and electron beam (EB) can also be applied. Examples thereof include a phenol novolac resin, a cresol novolac resin, a hydroxystyrene resin, a (meth)acrylic resin, a hydroxystyrene-(meth)acrylic copolymer, a cycloolefin-maleic anhydride copolymer, a cycloolefin, a vinyl ether-maleic anhydride copolymer, an inorganic resist material having a metallic element such as titanium, tin, hafnium and zirconium, and a derivative thereof. Examples of the derivative include, but are not particularly limited to, a derivative to which a dissociable group has been introduced and a derivative to which a crosslinkable group has been introduced. The composition for spin-on carbon film formation of the present embodiment may further contain a publicly known additive agent. Examples of the above publicly known additive agent include, but are not limited to, an ultraviolet absorber, a surfactant, a colorant, and a nonionic surfactant.

From the viewpoint of further improving storage stability, thin film formability, etching resistance, embedding properties, and flatness, as well as imparting a better resist pattern shape, it is particularly preferable that the composition for spin-on carbon film formation of the present embodiment contains, in addition to (i) below, at least one selected from the group consisting of the following (ii) to (iv):
(i) at least one dendritic polymer selected from the group consisting of a dendritic polymer containing a phenyl group, a biphenyl group, and/or a bisphenylene group (where the “bisphenyl group” is a divalent group having an arbitrary divalent group between two phenylene groups, such as -Ph-C(═O)-Ph-, -Ph-CH₂-Ph-, and -Ph-C(CH₃)₂-Ph-) in the molecule, a dendritic polymer containing an aromatic ring optionally having a heteroatom (for example, including a benzene ring and/or a triazine ring, etc.) in the molecule, and/or a dendritic polymer containing an azomethine bond (preferably a chemical structure in which R and R′ in the above formula (1) are each independently a phenylene group having —OH, —O—C(═O)—CH₃, or —O—CH₂—O—CH₃ as a substituent) in the molecule;
(ii) an acid generating agent selected from the group consisting of triphenylsulfonium nonafluorobutanesulfonate (for example, available under the trade name “TPS-109” or the like), di-tertiary butyl diphenyliodonium nonafluorobutanesulfonate (DTDPI), and pyridinium p-toluenesulfonate (PPTS);
(iii) a crosslinking agent selected from the group consisting of a compound represented by the above formula (a) (for example, available under the trade name “NIKALAC MW-100LM” or the like), a compound represented by the above formula (b) (for example, available under the trade name “NIKALAC MX270” or the like), and a methylol group-containing phenol compound represented by the above formula (11-2); and
(iv) a solvent selected from the group consisting of cyclohexanone, propylene glycol monomethyl ether, propylene glycol monomethyl ether acetate, ethyl lactate, methyl hydroxyisobutyrate, and anisole, and preferably a solvent selected from the group consisting of cyclohexanone, propylene glycol monomethyl ether, and propylene glycol monomethyl ether acetate.

### <Method for Producing Composition for Spin-On Carbon Film Formation>

The method for producing the composition for spin-on carbon film formation of the present embodiment is not particularly limited, and it can be produced as appropriate by mixing each component. In the present embodiment, from the viewpoint of further enhancing etching resistance, the composition for spin-on carbon film formation is preferably produced by the following method. That is, the method for producing the composition for spin-on carbon film formation of the present embodiment preferably includes an extraction step of bringing a solution containing the above dendritic polymer and an organic solvent that does not inadvertently mix with water into contact with an acidic aqueous solution, thereby carrying out extraction.

The purification method of the present embodiment specifically includes a step of dissolving the dendritic polymer in an organic solvent that does not inadvertently mix with water to obtain an organic phase, and bringing the organic phase into contact with an acidic aqueous solution to carry out extraction treatment (a first extraction step), thereby transferring metals contained in the organic phase containing the dendritic polymer and the organic solvent to an aqueous phase, and then separating the organic phase and the aqueous phase. This step can significantly reduce the content of various metals that can accompany the dendritic polymer.

In addition to the above, the method for producing the composition for spin-on carbon film formation of the present embodiment preferably includes a step of passing a solution in which the dendritic polymer is dissolved in a solvent through a filter. Also, the method for producing the composition for spin-on carbon film formation of the present embodiment preferably includes a step of bringing a solution in which the dendritic polymer is dissolved in a solvent into contact with an ion exchange resin. These production methods can also significantly reduce the content of various metals that can accompany the dendritic polymer.

Herein, the term “passing through” of the present embodiment means that the above solution is passed from the outside of the filter through the inside of the filter and is allowed to move out of the filter again. For example, an aspect in which the solution is simply brought into contact with the surface of the filter and an aspect in which the solution is brought into contact on the surface while being allowed to move outside the ion exchange resin (that is, an aspect in which the solution is simply brought into contact) are excluded.

### <Method for Forming Underlayer Film for Lithography>

A method for forming an underlayer film for lithography of the present embodiment (production method) includes a step of forming an underlayer film on a substrate using the composition for spin-on carbon film formation of the present embodiment.

### [Resist Pattern Formation Method Using Composition for Spin-On Carbon Film Formation]

A resist pattern formation method using the composition for spin-on carbon film formation of the present embodiment has steps of: forming an underlayer film on a substrate using the composition for spin-on carbon film formation of the present embodiment (step (A-1)); and forming at least one photoresist layer on the underlayer film (step (A-2)). The resist pattern formation method may further include a step of irradiating a predetermined region of the photoresist layer with radiation for development, thereby forming a resist pattern (step (A-3)).

### [Circuit Pattern Formation Method Using Composition for Spin-On Carbon Film Formation]

A circuit pattern formation method using the composition for spin-on carbon film formation of the present embodiment has steps of: forming an underlayer film on a substrate using the composition for spin-on carbon film formation of the present embodiment (step (B-1)); forming an intermediate layer film on the underlayer film using a silicon atom-containing resist intermediate layer film material (step (B-2)); forming at least one photoresist layer on the intermediate layer film (step (B-3)); after the step (B-3), irradiating a predetermined region of the photoresist layer with radiation for development, thereby forming a resist pattern (step (B-4)); after the step (B-4), etching the intermediate layer film with the resist pattern as a mask, thereby forming an intermediate layer film pattern (step (B-5)); etching the underlayer film with the obtained intermediate layer film pattern as an etching mask, thereby forming an underlayer film pattern (step (B-6)); and etching the substrate with the obtained underlayer film pattern as an etching mask, thereby forming a pattern on the substrate (step (B-7)).

The underlayer film for lithography of the present embodiment is not particularly limited by its formation method as long as it is formed from the composition for spin-on carbon film formation of the present embodiment. A publicly known approach can be applied thereto. The underlayer film can be formed by, for example, applying the composition for spin-on carbon film formation of the present embodiment onto a substrate by a publicly known coating method or printing method such as spin coating or screen printing, and then removing an organic solvent by volatilization or the like.

It is preferable to perform baking in the formation of the underlayer film, for preventing occurrence of a mixing event with an upper layer resist while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be selected as appropriate depending on the required performance and is not particularly limited, and is usually preferably about 30 to 20,000 nm, and more preferably 50 to 15,000 nm.

After preparing the underlayer film, it is preferable to prepare a silicon-containing resist layer or a usual single-layer resist containing hydrocarbon thereon in the case of a two-layer process, and to prepare a silicon-containing intermediate layer thereon and further a silicon-free single-layer resist layer thereon in the case of a three-layer process. In this case, a publicly known photoresist material can be used for forming this resist layer.

After preparing the underlayer film on the substrate, a silicon-containing resist layer or a usual single-layer resist containing hydrocarbon thereon can be prepared on the underlayer film in the case of a two-layer process. In the case of a three-layer process, a silicon-containing intermediate layer can be prepared on the underlayer film, and a silicon-free single-layer resist layer can be further prepared on the silicon-containing intermediate layer. In these cases, a publicly known photoresist material can be selected for use as appropriate, for forming the resist layer, without particular limitations.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond has been introduced is preferably used for exposure at 193 nm.

Alternatively, an intermediate layer formed by chemical vapor deposition (CVD) may be used. The intermediate layer highly effective as an antireflection film prepared by CVD is not limited, and a SiON film is known, for example. In general, the formation of an intermediate layer by a wet process such as spin coating or screen printing is more convenient and more advantageous in cost than CVD. The upper layer resist for a three-layer process may be positive type or negative type, and the same as a single-layer resist generally used can be used.

Furthermore, the underlayer film according to the present embodiment can also be used as an antireflection film for usual single-layer resists or an underlying material for suppression of pattern collapse. The underlayer film of the present embodiment is excellent in etching resistance for underlying processing and can be expected to also function as a hard mask for underlying processing.

In the above case of forming a resist layer from a photoresist material, a wet process such as spin coating or screen printing is preferably used, as in the above case of forming an underlayer film. After coating with the resist material by spin coating or the like, prebaking is generally performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly restricted, and in general, is preferably 30 to 500 nm and more preferably 50 to 400 nm.

The exposure light can be selected for use as appropriate depending on the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film according to the present embodiment. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed only with CO, CO₂, NH₃, N₂, NO₂, or H₂ gas without the use of oxygen gas. Particularly, the latter gas is preferably used for side wall protection in order to prevent the undercut of pattern side walls.

Meanwhile, gas etching is also preferably used as the etching of the intermediate layer in a three-layer process. The same gas etching as described in the above two-layer process is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, atomic layer deposition (ALD), or the like. A method for forming the nitride film is not limited, and, for example, the methods described in Japanese Patent Laid-Open No. 2002-334869 and International Publication No. WO 2004/066377 can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting effects as an antireflection film to the resist intermediate layer film, there is a tendency that reflection can be effectively suppressed. A specific material for the polysilsesquioxane-based intermediate layer is not limited, and, for example, those described in Japanese Patent Laid-Open No. 2007-226170 and Japanese Patent Laid-Open No. 2007-226204 can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film according to the present embodiment is that it is excellent in etching resistance of these substrates. The substrate can be selected from publicly known ones for use as appropriate, and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is generally used. The thickness of the substrate to be processed or the film to be processed is not particularly limited, and usually, it is preferably about 50 to 1,000,000 nm and more preferably 75 to 500,000 nm.

### <Underlayer Film for Lithography>

The underlayer film for lithography of the present embodiment can be obtained by, for example, spin coating the composition for spin-on carbon film formation of the present embodiment that contains a solvent. From the viewpoint of etching resistance, the underlayer film for lithography of the present embodiment preferably has an etching rate of 60 nm/min or less, the etching rate being measured by the following method.

### <Measurement of Etching Rate>

The underlayer film for lithography is subjected to the following etching test to measure an etching rate.

### (Etching Test)

Output: 100 W
Pressure: 8 Pa
Etching gas: CF₄ gas (flow rate 20 (sccm))

The above etching rate can be adjusted to the above range by using a composition for spin-on carbon film formation that contains the dendritic polymer and solvent according to the present embodiment, and in particular, it tends to be a low value by selecting the raw materials of the dendritic polymer as appropriate so that the dendritic polymer according to the present embodiment has the preferred chemical structure as described above, by controlling the molecular weight to the preferred range as described above, by using an acid generating agent or crosslinking agent, and by adjusting the conditions such as the heating temperature at the time of film formation as appropriate, for example.

### EXAMPLES

Hereinafter, the present embodiment will be described in more detail by means of Examples, but the present embodiment is not limited to these Examples.

### [Molecular Weight]

The molecular weight of a compound was measured by liquid chromatography-mass spectrometry (LC-MS) using Acquity UPLC/MALDI-Synapt HDMS manufactured by Waters Corporation.

Also, the weight average molecular weight (Mw), number average molecular weight (Mn), and dispersity (Mw/Mn) in terms of polystyrene were determined by gel permeation chromatography (GPC) analysis under the following conditions.
Apparatus: Shodex GPC-101 model (manufactured by Showa Denko K.K.)
Column: KF-80M×3
Eluent: 1 mL/min THF
Temperature: 40° C.

### [Structure of Compound]

The structure of a compound was confirmed by ¹H-NMR measurement using “Advance 60011 spectrometer” manufactured by Bruker Corp. under the following conditions.
Frequency: 400 MHz
Solvent: d6-DMSO
Internal standard: TMS
Measurement temperature: 23° C.

### [Initial Thermal Decomposition Temperature]

For the thermogravimetric start temperature of a compound, the EXSTAR 6000 TG-DTA apparatus manufactured by SII NanoTechnology Inc. was used. About 5 mg of the sample was placed in an unsealed container made of aluminum, and measurement was performed by raising the temperature to 500° C. at a temperature increase rate of 10° C./min in a nitrogen gas stream (300 mL/min). The portion at which a decrease in baseline appeared was defined as the thermal decomposition temperature.

### (Reference Example 1) Synthesis of BisP-1

A container (internal capacity: 500 mL) equipped with a stirrer, a condenser tube, and a burette was charged with 34.0 g (200 mmol) of o-phenylphenol (reagent manufactured by Sigma-Aldrich), 18.2 g (100 mmol) of 4-biphenylaldehyde (manufactured by Mitsubishi Gas Chemical Co., Inc.), and 200 mL of 1,4-dioxane, and 10 mL of 951 sulfuric acid was added. The reaction solution was stirred at 100° C. for 6 hours and reacted. Next, the reaction liquid was neutralized with 24% aqueous sodium hydroxide solution. The reaction product was precipitated by the addition of 100 g of pure water. After cooling to room temperature, the precipitates were separated by filtration. The solid matter obtained was dried and then separated and purified by column chromatography to obtain 25.5 g of a compound BisP-1 represented by the following formula (BisP-1).

As a result of subjecting the obtained compound to the above ¹H-NMR measurement, the following peaks were found, confirming that it has a chemical structure of the following formula (BisP-1).

δ (ppm) 9.1 (2H, O—H), 7.2-8.5 (25H, Ph-H), 5.6 (1H, C—H)

The above LC-MS analysis confirmed that the molecular weight was 504, which corresponds to the chemical structure of the following formula (BisP-1).

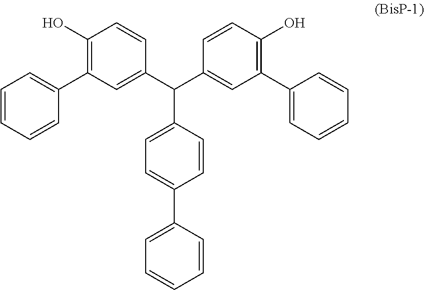 [SMILES: Oc1ccc(C(c2ccc(-c3ccccc3)cc2)c2ccc(O)c(-c3ccccc3)c2)cc1-c1ccccc1]

### <Synthesis Example 1> Synthesis of Compound D1

Except that the above formula (BiP-1) was used in place of calix[4]resorcinarene represented by formula (16) of Example 1 in Japanese Laid-Open No. 10-310545 (hereinafter, also referred to as “quoted Example a”), 1.2 g of a compound D1 represented by the following formula (D1) was obtained by performing the same operations as in quoted Example a.

As a result of subjecting the obtained compound to the above ¹H-NMR measurement, the following peaks were found, confirming that it has a chemical structure of the following formula (D1).

δ (ppm) (d6-DMSO): 9.1 (8H, O—H), 7.2-8.5 (43H, Ph-H), 5.6 (1H, C—H), 5.2 (12H, —CH₂—)

The above LC-MS analysis confirmed that the molecular weight was 1236, which corresponds to the chemical structure of the following formula (D1).

The above evaluation confirmed that the compound D1 is a dendritic polymer.

In addition, based on the above evaluation, the carbon content was evaluated to be 76.7%, the oxygen content to be 18.1, and the Si content and F content to be 0%.

The initial thermal decomposition temperature was higher than 300° C. and lower than 400° C.

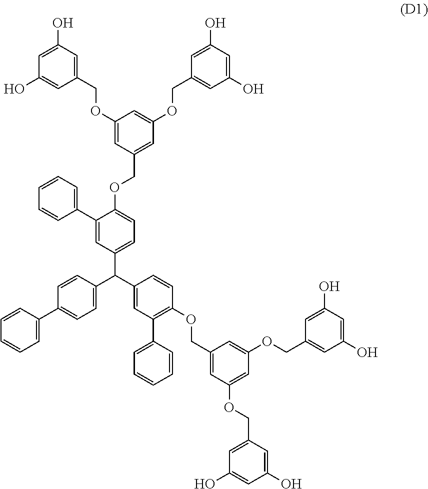 [SMILES: Oc1cc(O)cc(COc2cc(COc3ccc(C(c4ccc(-c5ccccc5)cc4)c4ccc(OCc5cc(OCc6cc(O)cc(O)c6)cc(OCc6cc(O)cc(O)c6)c5)c(-c5ccccc5)c4)cc3-c3ccccc3)cc(OCc3cc(O)cc(O)c3)c2)c1]

### <Synthesis Example 2> Synthesis of Compound D2

The reaction was carried out in the same manner as in Synthesis Example 1 in International Publication No. WO 2012/060286, after which the reaction liquid was concentrated and purified by column chromatography to obtain a compound D2′ represented by the following formula (D2′).

Next, 8.6 g (40 mmol) of 4,4′-dihydroxybenzophenone (MW 214), 4.0 g (10 mmol) of D2′ (Mw 399) obtained as described above, 11.2 g (100 mmol) of 1,4-diazabicyclo[2.2.2]octane (MW 112), and 100 mL of chlorobenzene were added to the reactor, which was heated to 90° C. and stirred. Thereafter, 22.8 g (120 mmol) of titanium chloride (MW 190) was added dropwise over 30 minutes. Subsequently, the temperature was raised to 125° C. and stirring was continued over 24 hours. Thereafter, the reaction liquid was concentrated and purified by column chromatography to obtain 0.5 g of a compound represented by the following formula (D2).

As a result of subjecting the obtained compound to the above ¹H-NMR measurement, the following peaks were found, confirming that it has a chemical structure of the following formula (D2).

δ (ppm) (d6-DMSO): 9.8 (6H, O—H), 9.4 (3H, N—H), 6.6-7.8 (36H, Ph-H)

The above LC-MS analysis confirmed that the molecular weight was 987, which corresponds to the chemical structure of the following formula (D2).

The above evaluation confirmed that the compound D2 is a dendritic polymer.

In addition, based on the above evaluation, the carbon content was evaluated to be 72.9%, the oxygen content to be 9.7%, and the Si content and F content to be 0%.

The initial thermal decomposition temperature was higher than 400° C.

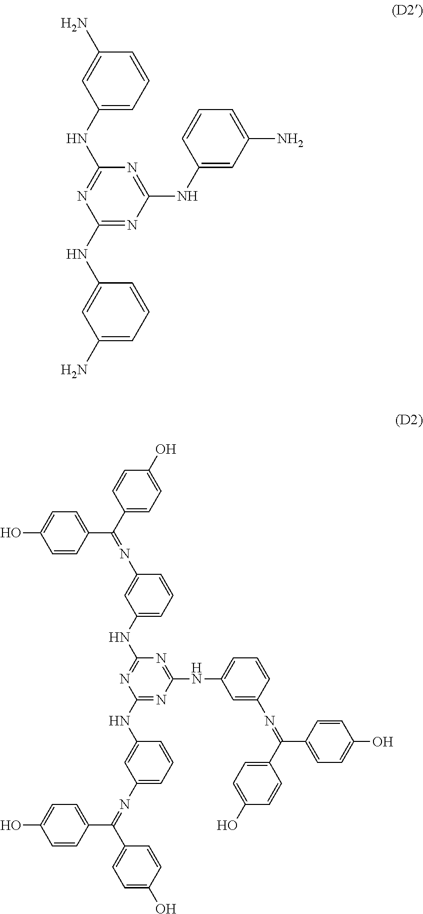 [SMILES: Nc1cccc(Nc2nc(Nc3cccc(N)c3)nc(Nc3cccc(N)c3)n2)c1 ; Oc1ccc(C(=Nc2cccc(Nc3nc(Nc4cccc(N=C(c5ccc(O)cc5)c5ccc(O)cc5)c4)nc(Nc4cccc(N=C(c5ccc(O)cc5)c5ccc(O)cc5)c4)n3)c2)c2ccc(O)cc2)cc1]

### <Synthesis Example 3> Synthesis of Compound D3

8.6 g (40 mmol) of 4,4′-dihydroxybenzophenone (MW 214), 2.1 g (10 mmol) of 3,3′-diaminobenzidine (MW 214), 11.2 g (100 mmol) of 1,4-diazabicyclo[2.2.2]octane (MW 112), and 100 mL of chlorobenzene were added to the reactor, which was heated to 90° C. and stirred. Thereafter, 22.8 g (120 mmol) of titanium chloride (MW 190) was added dropwise over 30 minutes. Subsequently, the temperature was raised to 125° C., and stirring was continued over 24 hours. Thereafter, the reaction liquid was concentrated and purified by column chromatography to obtain 2.5 g of a compound D3 represented by the following formula (D3).

As a result of subjecting the obtained compound to the above ¹H-NMR measurement, the following peaks were found, confirming that it has a chemical structure of the following formula (D3).

δ (ppm) (d6-DMSO): 9.9 (8H, OH), 6.8-7.8 (38H, Ph)

The above LC-MS analysis confirmed that the molecular weight was 998, which corresponds to the chemical structure of the following formula (D3).

The above evaluation confirmed that the compound D3 is a dendritic polymer.

In addition, based on the above evaluation, the carbon content was evaluated to be 76.9%, the oxygen content to be 12.8%, and the Si content and F content to be 0%.

The initial thermal decomposition temperature was higher than 400° C.

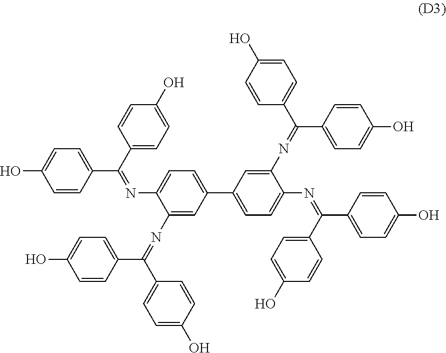 [SMILES: Oc1ccc(C(=Nc2ccc(-c3ccc(N=C(c4ccc(O)cc4)c4ccc(O)cc4)c(N=C(c4ccc(O)cc4)c4ccc(O)cc4)c3)cc2N=C(c2ccc(O)cc2)c2ccc(O)cc2)c2ccc(O)cc2)cc1]

### <Synthesis Example 4> Synthesis of Compound D4

8.6 g (40 mmol) of 4,4′-dihydroxybenzophenone (MW 214), 2.2 g (10 mmol) of 4,4′-diaminobenzophenone (MW 212), 11.2 g (100 mmol) of 1,4-diazabicyclo[2.2.2]octane (MW 112), and 100 mL of chlorobenzene were added to the reactor, which was heated to 90° C. and stirred. Thereafter, 22.8 g (120 mmol) of titanium chloride (MW 190) was added dropwise over 30 minutes. Next, the temperature was raised to 125° C. and stirring was continued over 24 hours. Thereafter, the reaction liquid was concentrated and purified by column chromatography to obtain 1.0 g of a compound D4 represented by the following formula (D4).

As a result of subjecting the obtained compound to the above ¹H-NMR measurement, the following peaks were found, confirming that it has a chemical structure of the following formula (D4).

δ (ppm) (d6-DMSO): 9.9 (1H, OH), 6.8-7.8 (13H, Ph)

Also, the above GPC analysis confirmed that Mw=3,828, Mn=1,823, and Mw/Mn=2.1.

The above evaluation confirmed that the compound D4 is a dendritic polymer.

In addition, based on the above evaluation, the carbon content was evaluated to be 70% or more, the oxygen content to be less than 20%, and the Si content and F content to be 0%.

The initial thermal decomposition temperature was higher than 400° C.

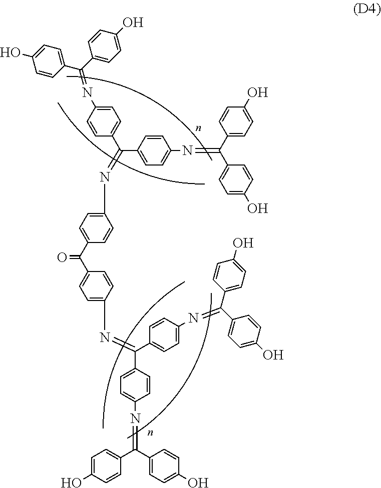

(wherein n is an integer of 0 to 3.)

### <Synthesis Example 5> Synthesis of Compound D5

8.6 g (40 mmol) of 4,4′-diaminobenzophenone (MW 212), 2.1 g (10 mmol) of 3,3′-diaminobenzidine (MW 214), 11.2 g (100 mmol) of 1,4-diazabicyclo[2.2.2]octane (MW 112), and 100 mL of chlorobenzene were added to the reactor, which was heated to 90° C. and stirred. Thereafter, 22.8 g (120 mmol) of titanium chloride (MW 190) was added dropwise over 30 minutes. Subsequently, 17.2 g (80 mmol) of 4,4′-dihydroxybenzophenone (MW 214) was added, the temperature was raised to 125° C., and stirring was continued over 24 hours. Thereafter, the reaction liquid was concentrated and purified by column chromatography to obtain 0.8 g of a compound D5 represented by the following formula (D5).

As a result of subjecting the obtained compound to the above ¹H-NMR measurement, the following peaks were found, confirming that it has a chemical structure of the following formula (D5).

δ (ppm) (d6-DMSO): 9.9 (8H, OH), 6.8-7.8 (57H, Ph) Also, the above GPC analysis confirmed that Mw=2,880, Mn=1,440, and Mw/Mn=2.0.

The above evaluation confirmed that the compound D5 is a dendritic polymer.

Also, based on the above evaluation, the carbon content was evaluated to be 70% or more, the oxygen content to be less than 20%, and the Si content and F content to be 0%.

The initial thermal decomposition temperature was higher than 400° C.

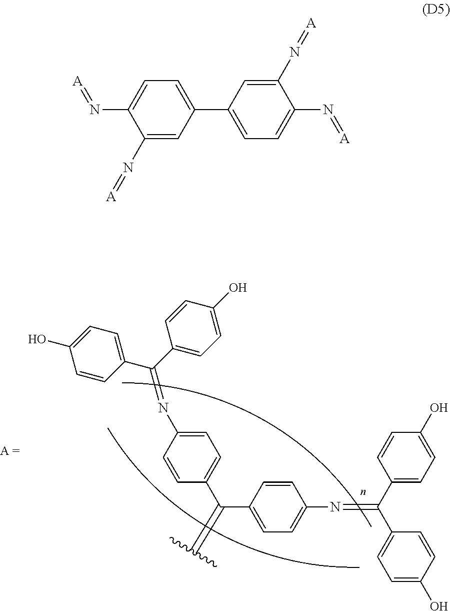

(wherein n is an integer of 0 to 3 and D5 is a mixture of n=0 to 3.)

### <Synthesis Example 6> Synthesis of Compound D6

A reactor was charged with the compound D3 of Synthesis Example 3 (22 g, 0.022 mol), 27 g (0.26 mol) of triethylamine, and 80 mL of tetrahydrofuran, and 16 g (0.16 mol) of acetic anhydride was further added. The reaction liquid was stirred at 60° C. for 5 hours and reacted. Next, 130 mL of 10% H₂SO₄ aqueous solution and 80 mL of ethyl acetate were added into the container, and the aqueous layer was then removed by liquid separation. Thereafter, the reaction liquid was concentrated and purified by column chromatography to obtain 21 g of a compound D6 represented by the following formula (D6).

As a result of subjecting the obtained compound to the above ¹H-NMR measurement, the following peaks were found, confirming that it has a chemical structure of the following formula (D6).

δ (ppm) (d6-DMSO): 6.8-7.8 (38H, Ph), 2.2 (24H, —CH₃)

The above LC-MS analysis confirmed that the molecular weight was 1334, which corresponds to the chemical structure of the following formula (D6).

The above evaluation confirmed that the compound D6 is a dendritic polymer.

In addition, based on the above evaluation, the carbon content was evaluated to be 72.0%, the oxygen content to be 19.21, and the Si content and F content to be 0%.

The initial thermal decomposition temperature was higher than 400° C.

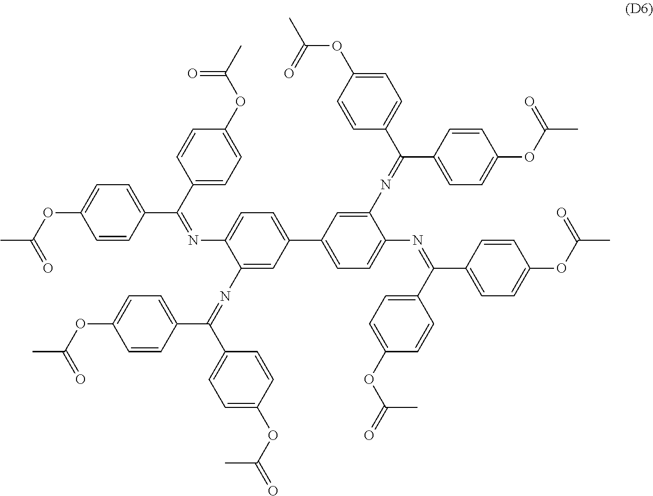 [SMILES: CC(=O)Oc1ccc(C(=Nc2ccc(-c3ccc(N=C(c4ccc(OC(C)=O)cc4)c4ccc(OC(C)=O)cc4)c(N=C(c4ccc(OC(C)=O)cc4)c4ccc(OC(C)=O)cc4)c3)cc2N=C(c2ccc(OC(C)=O)cc2)c2ccc(OC(C)=O)cc2)c2ccc(OC(C)=O)cc2)cc1]

### <Synthesis Example 7> Synthesis of Compound D7

A reactor was charged with the compound D3 of Synthesis Example 3 (22 g, 0.022 mol), 27 g (0.26 mol) of triethylamine, and 80 mL of tetrahydrofuran, and 8 g (0.08 mol) of acetic anhydride was further added. The reaction liquid was stirred at 60° C. for 5 hours and reacted. Next, 130 mL of 10% H₂SO₄ aqueous solution and 80 mL of ethyl acetate were added into the container, and then the aqueous layer was removed by liquid separation. Thereafter, the reaction liquid was concentrated and purified by column chromatography to obtain 19 g of a compound D7 represented by the following formula (D7).

As a result of subjecting the obtained compound to the above ¹H-NMR measurement, the following peaks were found, confirming that it has the chemical structure below.

δ (ppm) (d6-DMSO): 9.9 (4H, OH), 6.8-7.8 (38H, Ph), 2.2 (12H, —CH₃)

The above evaluation confirmed that the compound D7 is a dendritic polymer.

In addition, based on the above evaluation, the carbon content was evaluated to be 74.5%, the oxygen content to be 16.0%, and the Si content and F content to be 0%.

The initial thermal decomposition temperature was higher than 400° C.

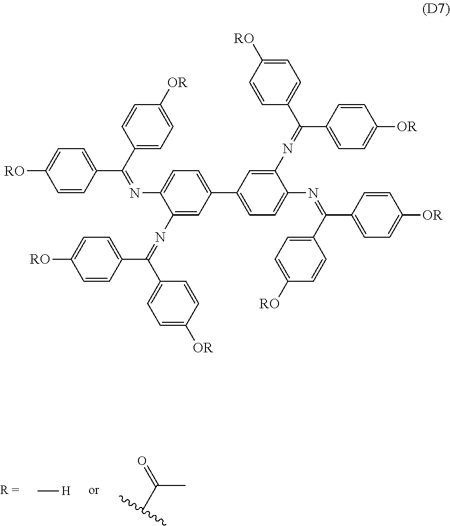

(D7 is a mixture of R=H and R=—CH₂OCH₃, and the protection ratio was evaluated to be about 50 mol % from the integral ratio of the above ¹H-NMR measurement. The above protection ratio is also consistent with the identification results in the compound D6 and the relationship with the amount of acetic anhydride used.)

### <Synthesis Example 8> Synthesis of Compound D8

A reactor was charged with the compound D3 of Synthesis Example 3 (22 g, 0.022 mol), 27 g (0.26 mol) of triethylamine, and 80 mL of tetrahydrofuran, and 16 g (0.16 mol) of methoxymethoxy chloride was further added. The reaction liquid was stirred at 60° C. for 5 hours and reacted. Next, 130 mL of 10% H₂SO₄ aqueous solution and 80 mL of ethyl acetate were added into the container and the aqueous layer was then removed by liquid separation. Thereafter, the reaction liquid was concentrated and purified by column chromatography to obtain 20 g of a compound D8 represented by the following formula (D8).

As a result of subjecting the obtained compound to the above ¹H-NMR measurement, the following peaks were found, confirming that it has the chemical structure below.

δ (ppm) (d6-DMSO): 6.8-7.8 (38H, Ph), 6.0 (16H, —CH₂—), 3.3 (24H, —CH₃)

The above LC-MS analysis confirmed that the molecular weight was 1351, which corresponds to the chemical structure of the following formula (D8).

The above evaluation confirmed that the compound D8 is a dendritic polymer.

In addition, based on the above evaluation, the carbon content was evaluated to be 71.3%, the oxygen content to be 17.7%, and the Si content and F content to be 0%.

The initial thermal decomposition temperature was higher than 400° C.

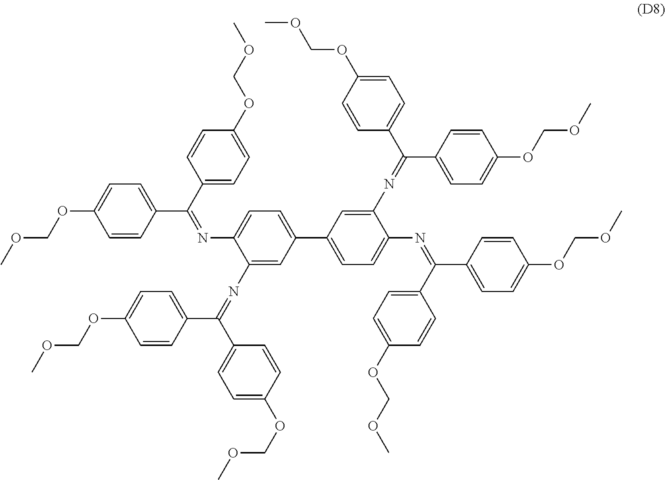

### <Synthesis Example 9> Synthesis of Compound D9

A reactor was charged with the compound D3 of Synthesis Example 3 (22 g, 0.022 mol), 27 g (0.26 mol) of triethylamine, and 80 mL of tetrahydrofuran, and 8 g (0.08 mol) of methoxymethoxy chloride was further added. The reaction liquid was stirred at 60° C. for 5 hours and reacted. Next, 130 mL of 10% H₂SO₄ aqueous solution and 80 mL of ethyl acetate were added into the container and then the aqueous layer was removed by liquid separation. Thereafter, the reaction liquid was concentrated and purified by column chromatography to obtain 18 g of a compound D9 represented by the following formula (D9).

As a result of subjecting the obtained compound to the above ¹H-NMR measurement, the following peaks were found, confirming that it has the chemical structure below.

δ (ppm) (d6-DMSO): 9.9 (4H, OH), 6.8-7.8 (38H, Ph), 6.0 (8H, —CH₂—), 3.3 (12H, —CH₃)

The above evaluation confirmed that the compound D9 is a dendritic polymer.

In addition, based on the above evaluation, the carbon content was evaluated to be 74.1%, the oxygen content to be 15.3%, and the Si content and F content to be 0%.

The initial thermal decomposition temperature was higher than 400° C.

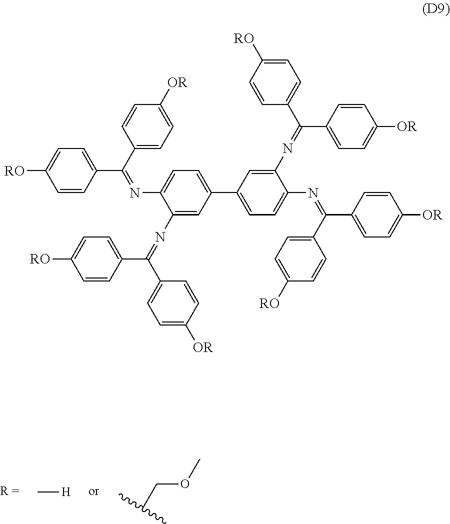

(D9 is a mixture of R=H and R=—CH₂OCH₃, and the protection ratio was evaluated to be about 50 mol % from the integral ratio of the above ¹H-NMR measurement.)

### <Synthesis Comparative Example 1> Synthesis of AC-1

4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The obtained product resin was solidified and purified, and the resulting white powder was filtered and then dried overnight at 40° C. under reduced pressure to obtain a compound AC-1 represented by the formula below. The compound AC-1 was evaluated to not fall within dendritic polymers since it has two terminal groups and a degree of branching of 0.

The initial thermal decomposition temperature was lower than 300° C.

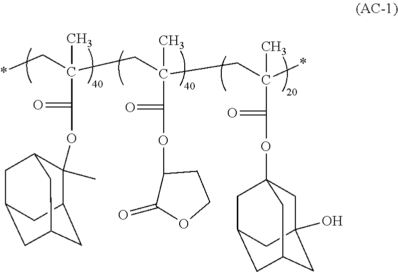

(wherein “40”, “40”, and “20” represent the ratio of each constitutional unit and do not indicate a block copolymer.)

### (Evaluation 1) Test of Solubility of Compound in Semiconductor Coating Solvent

The solubility of a compound in PGME, PGMEA, and CHN was evaluated based on the following criteria using the amount of dissolution in each solvent. The amount of dissolution was measured at 23° C. by precisely weighing the compound into a test tube, adding the subject solvent so as to attain a predetermined concentration, applying ultrasonic waves for 30 minutes in an ultrasonic cleaner, and then visually observing the subsequent state of the fluid. In the case where the amount of dissolution is 0.5% by mass, each Example was adjusted so that the solvent was added to 0.05 g of solute, resulting in a total of 10.00 g.
A: 0.5% by mass ≤ amount of dissolution
C: amount of dissolution <0.5% by mass

### Examples 1-1 to 9-1 and Comparative Example 1-1

Table 1 shows the results of evaluating the solubility of the compounds obtained in Synthesis Examples 1 to 5 and Synthesis Comparative Example 1 in the semiconductor coating solvents by the above method.

TABLE 1

| | Compound | PGME | PGMEA | CHN |
|---|---|---|---|---|
| Example 1-1 | Synthesis Example 1 | A | A | A |
| Example 2-1 | Synthesis Example 2 | A | A | A |
| Example 3-1 | Synthesis Example 3 | A | A | A |
| Example 4-1 | Synthesis Example 4 | A | A | A |
| Example 5-1 | Synthesis Example 5 | A | A | A |
| Example 6-1 | Synthesis Example 6 | A | A | A |
| Example 7-1 | Synthesis Example 7 | A | A | A |
| Example 8-1 | Synthesis Example 8 | A | A | A |
| Example 9-1 | Synthesis Example 9 | A | A | A |
| Comparative | Synthesis Comparative | A | A | A |
| Example 1-1 | Example 1 | | | |

### Examples 1-2-1 to 9-2-2 and Comparative Example 1-2

The compositions for spin-on carbon film formation were each prepared with the compositional features shown in Table 2 below.

Next, a silicon substrate was spin coated with each of these compositions for spin-on carbon film formation, and then baked at 110° C. for 90 seconds to prepare the respective films with a film thickness of 50 nm. The following acid generating agents, crosslinking agents, and organic solvents were used.

### Acid Generating Agent:

triphenylsulfonium nonafluorobutanesulfonate (TPS-109) manufactured by Midori Kagaku Co., Ltd.
di-tertiary butyl diphenyliodonium nonafluorobutanesulfonate (DTDPI) manufactured by Midori Kagaku Co., Ltd.
pyridinium p-toluenesulfonate (in the table, denoted as “PPTS”) manufactured by Kanto Chemical Co., Inc.

### Crosslinking Agent:

NIKALAC MW-100LM manufactured by Sanwa Chemical Co., Ltd. NIKALAC MX270 manufactured by Sanwa Chemical Co., Ltd.
   TMOM-BP manufactured by Honshu Chemical Industry Co., Ltd.

### Organic Solvent:

propylene glycol monomethyl ether (PGME) manufactured by Kanto Chemical Co., Inc.
propylene glycol monomethyl ether acetate (PGMEA) manufactured by Kanto Chemical Co., Inc.
cyclohexanone (CHN) manufactured by Kanto Chemical Co., Inc.

Subsequently, evaluation was performed by each of the following methods. The evaluation results are shown in Table 2.

### (Evaluation 2) Storage Stability and Thin Film Formation of Composition for Spin-On Carbon Film Formation

After the composition for spin-on carbon film formation was prepared, it was allowed to stand at 23° C. for 3 days and evaluated by visual observation for the presence of precipitates.

Also, for the compositions for spin-on carbon film formation and the films formed as described above using them, they were evaluated as “A” in the case where the solution was homogeneous and the thin film formation was good, “B” in the case where the solution was homogeneous but there were defects in the thin film, and “C” in the case where there were precipitates.

### (Evaluation 3) Etching Resistance

For the films obtained in the above Evaluation 2, the etching test was carried out under the following conditions, and the etching rate upon that time was measured.
Etching apparatus: RIE-10NR manufactured by Samco International, Inc.
Output: 100 W
Pressure: 8 Pa
Etching gas: CF₄ gas (flow rate 20 (sccm))

### (Evaluation Criteria)

A: Etching rate is less than 40 nm/min
B: Etching rate is 40 nm/min or more and less than 60 nm/min
C: Etching rate is 60 nm/min or more

### (Evaluation 4) Embedding Properties

A SiO₂ substrate having a line and space pattern of 60 nm was coated with each composition for spin-on carbon film formation, and baked at 400° C. for 60 seconds to form a film of about 100 nm. The cross section of the obtained film was cut out and observed with an electron microscope (“S-4800” from Hitachi High-Technologies Corporation) to evaluate the embedding properties of the composition for underlayer film formation for lithography to the substrate having difference in level according to the following evaluation criteria. The results are shown in Table 2.

### <Evaluation Criteria>

S: The underlayer film was embedded to the asperities of the SiO₂ substrate with no defects (the number of defects in the range of 1 μm×1.5 μm was 0).
A: The underlayer film was embedded to the asperities of the SiO₂ substrate with almost no defects (the number of defects in the range of 1 μm×1.5 μm was 1 to 2).
C: There were defects in the asperities of the SiO₂ substrate (the number of defects in the range of 1 μm×1.5 μm was 3 or more), and the underlayer film was not embedded.

### (Evaluation 5) Smoothing Properties

A SiO₂ uneven substrate having a trench with a width of 60 nm, a pitch of 60 nm, and a depth of 200 nm was coated with each composition for spin-on carbon film formation. Thereafter, it was calcined at 400° C. for 60 seconds under the air atmosphere to form an underlayer film with a film thickness of 100 nm. The shape of this underlayer film was observed with a scanning electron microscope (“S-4800” from Hitachi High-Technologies Corporation), and the difference between the minimum value of the film thickness on the trench and the maximum value of the film thickness on a part not having the trench (ΔFT) was calculated to evaluate the smoothing properties according to the following evaluation criteria. The results are shown in Table 2.

### <Evaluation Criteria>

S: ΔFT<20 nm (brilliant flatness)
A: 20 nm≤ΔFT<30 nm (good flatness)
C: 30 nm≤ΔFT (poor flatness)

TABLE 2

| | | Acid generating | Crosslinking | Organic | Storage | | | |
|---|---|---|---|---|---|---|---|---|
| | Compound | agent | agent | solvent | stability | | | |
| | (parts | (parts | (parts | (parts | (thin film | Etching | Embedding | Smoothing |
| | by mass) | by mass) | by mass) | by mass) | formation) | resistance | properties | properties |
| Example | Synthesis | TPS-109(1) | MW-100LM(1) | CHN(250) | A | A | S | S |
| 1-2-1 | Example 1(5) | | | | | | | |
| Example | Synthesis | TPS-109(1) | None | CHN(250) | A | A | S | S |
| 1-2-2 | Example 1(5) | | | | | | | |
| Example | Synthesis | TPS-109(1) | MW-100LM(1) | PGMEA(250) | A | A | S | S |
| 2-2-1 | Example 2(5) | | | | | | | |
| Example | Synthesis | TPS-109(1) | None | PGMEA(250) | A | A | S | S |
| 2-2-2 | Example 2(5) | | | | | | | |
| Example | Synthesis | TPS-109(1) | MW-100LM(1) | CHN(500) | A | A | S | S |
| 3-2-1 | Example 3(5) | | | | | | | |
| Example | Synthesis | TPS-109(1) | None | CHN(500) | A | A | S | S |
| 3-2-2 | Example 3(5) | | | | | | | |
| Example | Synthesis | TPS-109(1) | MW-100LM(1) | CHN(500) | A | A | A | A |
| 4-2-1 | Example 4(5) | | | | | | | |
| Example | Synthesis | TPS-109(1) | None | CHN(500) | A | A | A | A |
| 4-2-2 | Example 4(5) | | | | | | | |
| Example | Synthesis | TPS-109(1) | MW-100LM(1) | CHN(500) | A | A | A | A |
| 5-2-1 | Example 5(5) | | | | | | | |
| Example | Synthesis | TPS-109(1) | None | CHN(500) | A | A | A | A |
| 5-2-2 | Example 5(5) | | | | | | | |
| Example | Synthesis | TPS-109(1) | MX270(1) | CHN(500) | A | A | A | A |
| 5-2-3 | Example 5(5) | | | | | | | |
| Example | Synthesis | TPS-109(1) | TMOM-BP(1) | CHN(500) | A | A | A | A |
| 5-2-4 | Example 5(5) | | | | | | | |
| Example | Synthesis | DTDPI(1) | MW-100LM(1) | CHN(500) | A | A | A | A |
| 5-2-5 | Example 5(5) | | | | | | | |
| Example | Synthesis | PPTS(1) | MW-100LM(1) | CHN(500) | A | A | A | A |
| 5-2-6 | Example 5(5) | | | | | | | |
| Example | Synthesis | DTDPI(2) | MW-100LM(2) | CHN(500) | A | A | A | A |
| 5-2-7 | Example 5(5) | | | | | | | |
| Example | Synthesis | TPS-109(1) | MW-100LM(1) | CHN(500) | A | A | A | A |
| 6-2-1 | Example 6(5) | | | | | | | |
| Example | Synthesis | TPS-109(1) | None | CHN(500) | A | A | A | A |
| 6-2-2 | Example 6(5) | | | | | | | |
| Example | Synthesis | TPS-109(1) | MW-100LM(1) | CHN(500) | A | A | A | A |
| 7-2-1 | Example 7(5) | | | | | | | |
| Example | Synthesis | TPS-109(1) | None | CHN(500) | A | A | A | A |
| 7-2-2 | Example 7(5) | | | | | | | |
| Example | Synthesis | TPS-109(1) | MW-100LM(1) | CHN(500) | A | A | A | A |
| 8-2-1 | Example 8(5) | | | | | | | |
| Example | Synthesis | TPS-109(1) | None | CHN(500) | A | A | A | A |
| 8-2-2 | Example 8(5) | | | | | | | |
| Example | Synthesis | TPS-109(1) | MW-100LM(1) | CHN(500) | A | A | A | A |
| 9-2-1 | Example 9(5) | | | | | | | |
| Example | Synthesis | TPS-109(1) | None | CHN(500) | A | A | A | A |
| 9-2-2 | Example 9(5) | | | | | | | |
| Comparative | Synthesis | TPS-109(1) | None | PGME(250) | A | C | C | C |
| Example 1-2 | Comparative | | | | | | | |
| | Example 1(5) | | | | | | | |

### Examples 1-3-1 to 9-3-2 and Comparative Example 2

### <Synthesis of MAR1>

0.5 g of a compound AR1 (compound represented by the formula (AR1) below), 3.0 g of 2-methyl-2-adamantyl methacrylate, 2.0 g of γ-butyrolactone methacrylate, and 1.5 g of hydroxyadamantyl methacrylate were dissolved in 45 mL of tetrahydrofuran, and 0.20 g of azobisisobutyronitrile was added thereto. After the mixture was refluxed for 12 hours, the reaction solution was added dropwise to 2 L of n-heptane. The polymer precipitated was filtered off and dried under reduced pressure to obtain a white powdery polymer MAR1 represented by the formula (MAR1) below. This polymer had a weight average molecular weight (Mw) of 12,000 and a dispersity (Mw/Mn) of 1.90. As a result of the measurement of ¹³C-NMR, the composition ratio (molar ratio) in the formula (MAR1) below was a:b:c:d=40:30:15:15. Although the formula (MAR1) below is illustrated in a simplified form to show the ratio of the respective constitutional units, the order of arrangement of the respective constitutional units is random and this polymer is not a block copolymer in which the respective constitutional units form independent blocks. The molar ratio was determined based on the integral ratio of each of the carbon on the bottom of a benzene ring for the polystyrene monomer (the compound AR1) and the carbonyl carbon of an ester bond for methacrylate monomers (2-methyl-2-adamantyl methacrylate, γ-butyrolactone methacrylate, and hydroxyadamantyl methacrylate).

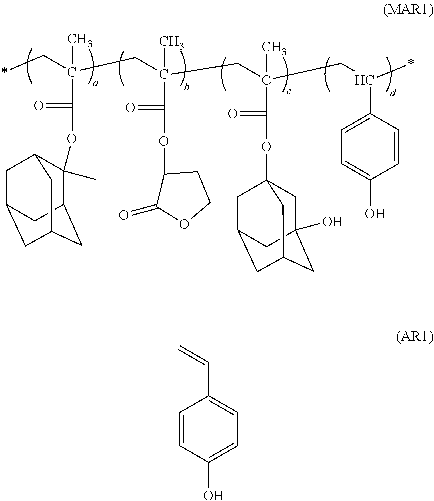

### Examples 1-3-1 to 9-3-2 and Comparative Example 2

### (Preparation of Underlayer Film Forming Solution)

The compositions for spin-on carbon film formation were each prepared with the compositional features shown in Table 3 below.

### [Evaluation]

A SiO₂ substrate with a film thickness of 300 nm was spin coated with each of the compositions for spin-on carbon film formation prepared in Examples 1-2-1 to 9-2-2 described above, and baked at 150° C. for 60 seconds and further at 400° C. for 120 seconds to thereby form an underlayer film with a film thickness of 70 nm. This underlayer film was coated with a resist solution for ArF and baked at 130° C. for 60 seconds to thereby form a photoresist layer with a film thickness of 140 nm. The ArF resist solution used was prepared by compounding 5 parts by mass of the compound represented by the formula (MAR1), 1 part by mass of triphenylsulfonium nonafluorobutanesulfonate, 2 parts by mass of tributylamine, and 92 parts by mass of PGMEA.

Subsequently, the photoresist layer was exposed with a design of 45 nm L/S (1:1), 50 nm L/S (1:1), 55 nm L/S (1:1), and 80 nm L/S (1:1) using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern.

Defects of the obtained resist patterns of 55 nm L/S (1:1) and 80 nm L/S (1:1) were observed, and the results are shown in Table 3. In the table, for the shape of the resist pattern after development, “Good” means that no major defects were found in the formed resist patterns each having a line width of 55 nm L/S (1:1) and 80 nm L/S (1:1), and “Poor” means that major defects were found in the formed resist pattern having either line width. In the table, “Resolution” is the minimum line width with no pattern collapse and good rectangularity, and “Sensitivity” indicates the minimum amount of electron beam energy capable of forming a good pattern shape.

### Comparative Example 2

The evaluation was performed in the same manner as in Example 1-3-1, except that no underlayer film was formed.

TABLE 3

| | | Acid generating | Crosslinking | Organic | | | |
|---|---|---|---|---|---|---|---|
| | Compound | agent | agent | solvent | Resolution | | Resist |
| | (parts | (parts | (parts | (parts | (nm | Sensitivity | pattern |
| | by mass) | by mass) | by mass) | by mass) | L/S) | (μC/cm²) | shape |
| Example | Synthesis | TPS-109(1) | MW-100LM(1) | PGMEA/PGME(200/50) | 50 | 10 | Good |
| 1-3-1 | Example 1(5) | | | | | | |
| Example | Synthesis | TPS-109(1) | None | PGMEA/PGME(200/50) | 50 | 10 | Good |
| 1-3-2 | Example 1(5) | | | | | | |
| Example | Synthesis | TPS-109(1) | MW-100LM(1) | PGMEA/PGME(200/50) | 45 | 10 | Good |
| 2-3-1 | Example 2(5) | | | | | | |
| Example | Synthesis | TPS-109(1) | None | PGMEA/PGME(200/50) | 45 | 10 | Good |
| 2-3-2 | Example 2(5) | | | | | | |
| Example | Synthesis | TPS-109(1) | MW-100LM(1) | CHN(500) | 45 | 10 | Good |
| 3-3-1 | Example 3(5) | | | | | | |
| Example | Synthesis | TPS-109(1) | None | CHN(500) | 45 | 10 | Good |
| 3-3-2 | Example 3(5) | | | | | | |
| Example | Synthesis | TPS-109(1) | MW-100LM(1) | CHN(500) | 40 | 10 | Good |
| 4-3-1 | Example 4(5) | | | | | | |
| Example | Synthesis | TPS-109(1) | None | CHN(500) | 40 | 10 | Good |
| 4-3-2 | Example 4(5) | | | | | | |
| Example | Synthesis | TPS-109(1) | MW-100LM(1) | CHN(500) | 40 | 10 | Good |
| 5-3-1 | Example 5(5) | | | | | | |
| Example | Synthesis | TPS-109(1) | None | CHN(500) | 40 | 10 | Good |
| 5-3-2 | Example 5(5) | | | | | | |
| Example | Synthesis | TPS-109(1) | MW-100LM(1) | CHN(500) | 40 | 10 | Good |
| 6-3-1 | Example 6(5) | | | | | | |
| Example | Synthesis | TPS-109(1) | None | CHN(500) | 40 | 10 | Good |
| 6-3-2 | Example 6(5) | | | | | | |
| Example | Synthesis | TPS-109(1) | MW-100LM(1) | CHN(500) | 40 | 10 | Good |
| 7-3-1 | Example 7(5) | | | | | | |
| Example | Synthesis | TPS-109(1) | None | CHN(500) | 40 | 10 | Good |
| 7-3-2 | Example 7(5) | | | | | | |
| Example | Synthesis | TPS-109(1) | MW-100LM(1) | CHN(500) | 40 | 10 | Good |
| 8-3-1 | Example 8(5) | | | | | | |
| Example | Synthesis | TPS-109(1) | None | CHN(500) | 40 | 10 | Good |
| 8-3-2 | Example 8(5) | | | | | | |
| Example | Synthesis | TPS-109(1) | MW-100LM(1) | CHN(500) | 40 | 10 | Good |
| 9-3-1 | Example 9(5) | | | | | | |
| Example | Synthesis | TPS-109(1) | None | CHN(500) | 40 | 10 | Good |
| 9-3-2 | Example 9(5) | | | | | | |

| | | | | |
|---|---|---|---|---|
| Comparative | None | 80 | 26 | Poor |
| Example 2 | | | | |

As described above, the composition for spin-on carbon film formation of the present embodiment has excellent storage stability, thin film formability, etching resistance, embedding properties, and flatness, and can impart a good resist pattern shape.

Therefore, when it is used in compositions for applications of film formation for photolithography or applications of underlayer film formation, it is possible to form a film having high resolution and high sensitivity, and to form a good resist pattern. It can be widely and effectively utilized in various applications where such performance is required.

### INDUSTRIAL APPLICABILITY

The composition for spin-on carbon film formation of the present invention has industrial applicability as a composition material for applications of film formation for photolithography and for applications of underlayer film formation.

1. A composition for spin-on carbon film formation, that is a composition for forming a spin-on carbon film as an underlayer film for lithography, comprising
a dendritic polymer.

2. The composition for spin-on carbon film formation according to claim 1, wherein the dendritic polymer has an ester bond, a ketone bond, an amide bond, an imide bond, a urea bond, a urethane bond, an ether bond, a thioether bond, an imino bond, and/or an azomethine bond in a molecule.

3. The composition for spin-on carbon film formation according to claim 1, wherein the dendritic polymer has a chemical structure represented by the following formula (1) in a molecule:
R(R′)C═N— (1)
wherein R and R′ each independently represent an arylene group optionally having a substituent.

4. The composition for spin-on carbon film formation according to claim 1, wherein the dendritic polymer has an initial thermal decomposition temperature of 300° C. or higher.

5. The composition for spin-on carbon film formation according to claim 1, wherein the dendritic polymer has a solubility in a semiconductor coating solvent of 0.5% by mass or more.

6. The composition for spin-on carbon film formation according to claim 1, wherein the dendritic polymer has a carbon content of 70% or more, and/or the dendritic polymer has an oxygen content of less than 20%.

7. The composition for spin-on carbon film formation according to claim 1, further comprising a solvent.

8. The composition for spin-on carbon film formation according to claim 7, further comprising at least one selected from the group consisting of an acid generating agent and a crosslinking agent.

9. An underlayer film for lithography comprising the composition for spin-on carbon film formation according to claim 7,
wherein an etching rate is 60 nm/min or less, the etching rate being measured by the following method:
<Measurement of Etching Rate>
the underlayer film for lithography is subjected to the following etching test to measure the etching rate:
(Etching Test)
Output: 100 W
Pressure: 8 Pa
Etching gas: CF₄ gas (flow rate 20 (sccm)).

10. A resist pattern formation method, comprising:
an underlayer film formation step of forming an underlayer film on a substrate using the composition for spin-on carbon film formation according to claim 1;
a photoresist layer formation step of forming at least one photoresist layer on the underlayer film formed through the underlayer film formation step; and
a step of irradiating a predetermined region of the photoresist layer formed through the photoresist layer formation step with radiation for development.

11. A circuit pattern formation method, comprising:
an underlayer film formation step of forming an underlayer film on a substrate using the composition for spin-on carbon film formation according to claim 1;
an intermediate layer film formation step of forming an intermediate layer film on the underlayer film formed through the underlayer film formation step;
a photoresist layer formation step of forming at least one photoresist layer on the intermediate layer film formed through the intermediate layer film formation step;
a resist pattern formation step of irradiating a predetermined region of the photoresist layer formed through the photoresist layer formation step with radiation for development, thereby forming a resist pattern;
an intermediate layer film pattern formation step of etching the intermediate layer film with the resist pattern formed through the resist pattern formation step as a mask, thereby forming an intermediate layer film pattern;
an underlayer film pattern formation step of etching the underlayer film with the intermediate layer film pattern formed through the intermediate layer film pattern formation step as a mask, thereby forming an underlayer film pattern; and
a substrate pattern formation step of etching the substrate with the underlayer film pattern formed through the underlayer film pattern formation step as a mask, thereby forming a pattern on the substrate.

12. A method for producing the composition for spin-on carbon film formation according to claim 1, comprising
an extraction step of bringing a solution comprising the dendritic polymer and an organic solvent that does not inadvertently mix with water into contact with an acidic aqueous solution, thereby carrying out extraction.

13. A method for producing the composition for spin-on carbon film formation according to claim 1, comprising a step of passing a solution in which the dendritic polymer is dissolved in a solvent through a filter.

14. A method for producing the composition for spin-on carbon film formation according to claim 1, comprising a step of bringing a solution in which the dendritic polymer is dissolved in a solvent into contact with an ion exchange resin.
